(19) United States
(12) Patent Application Publication
(10) Pub. No.: US 2024/0379729 A1
(43) Pub. Date: Nov. 14, 2024

(54) DISPLAY DEVICE

(71) Applicant: Samsung Display Co., LTD., Yongin-si (KR)

(72) Inventors: Jong Hwan PARK, Yongin-si (KR); Ki Nyeng KANG, Yongin-si (KR); Jong Hwan CHA, Yongin-si (KR)

(21) Appl. No.: 18/651,103

(22) Filed: Apr. 30, 2024

(30) Foreign Application Priority Data
May 8, 2023 (KR) 10-2023-0059093

(51) Int. Cl. H01L 27/15

(52) U.S. Cl. CPC H01L 27/156

(57) ABSTRACT

A display device includes: a substrate including a first pixel and a second pixel that are adjacent to each other in a first direction, the first pixel including a sub-pixel and the second pixel including sub-pixel; a first electrode and a second electrode above the substrate and extending in the first direction, the first electrode and the second electrode being in the sub-pixels; a first insulating layer above the first electrode and the second electrode; light-emitting elements above the first insulating layer between the first electrode and the second electrode; a bank layer above the first insulating layer and dividing a first emission area and a second emission area of one of the sub-pixels and dividing a sub-area of the first pixel and a sub-area of the second pixel; and a first connection electrode and a second connection electrode in the sub-pixels.

### CROSS-REFERENCE TO RELATED APPLICATION

The present application claims priority to and the benefit of Korean Patent Application No. 10-2023-0059093, filed on May 8, 2023, in the Korean Intellectual Property Office, the entire content of which is incorporated by reference herein.

### BACKGROUND

### 1. Field

The present disclosure relates to a display device.

### 2. Description of Related Art

The importance of display devices has steadily increased with the development of multimedia technology. In response thereto, various types of display devices such as an organic light-emitting diode (OLED) display, a liquid crystal display (LCD) and the like have been used.

A display device is a device for displaying an image, and may include a display panel, such as a light-emitting display panel or a liquid crystal display panel. The light-emitting display panel may include light-emitting elements, e.g., light-emitting diodes (LED). The light-emitting diode may include an organic light-emitting diode (OLED) using an organic material as a light-emitting material and an inorganic light-emitting diode using an inorganic material as a light-emitting material.

### SUMMARY

Aspects of the present disclosure provide a display device capable of preventing or reducing dark spot defects.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

In one or more embodiments, a display device includes: a substrate including a first pixel and a second pixel that are adjacent to each other in a first direction, the first pixel including a sub-pixel and the second pixel including sub-pixel; a first electrode and a second electrode above the substrate and extending in the first direction, the first electrode and the second electrode being in the sub-pixels; a first insulating layer above the first electrode and the second electrode; light-emitting elements above the first insulating layer between the first electrode and the second electrode; a bank layer above the first insulating layer and dividing a first emission area and a second emission area of one of the sub-pixels and dividing a sub-area of the first pixel and a sub-area of the second pixel; and a first connection electrode and a second connection electrode in the sub-pixels, the first connection electrode being connected to a first end of the light-emitting elements, and the second connection electrode connected to a second end of the light-emitting elements, wherein the bank layer is around the first emission area and the sub-area of the sub-pixel of the first pixel and the second emission area of the sub-pixel of the second pixel.

In one or more embodiments, the bank layer includes: a first extension and a second extension extending in the first direction and spaced in a second direction crossing the first direction; and a first connection and a second connection connecting the first extension and the second extension, and spaced in the first direction.

In one or more embodiments, the first extension is at one side of the sub-pixels of the first pixel and the second pixel, and wherein the second extension is at an other side of the sub-pixels of the first pixel and the second pixel.

In one or more embodiments, the first connection is in the sub-pixel of the first pixel between the first emission area and the second emission area of the sub-pixel of the first pixel.

In one or more embodiments, the first connection electrode of the sub-pixel of the first pixel does not overlap the first connection, and wherein the second connection electrode of the sub-pixel of the first pixel overlaps the first connection.

In one or more embodiments, the second connection is in the sub-pixel of the second pixel between the first emission area and the second emission area of the sub-pixel of the second pixel.

In one or more embodiments, the first connection electrode of the sub-pixel of the second pixel does not overlap the second connection, and wherein the second connection electrode of the sub-pixel of the second pixel overlaps the second connection.

In one or more embodiments, the first extension, the second extension, the first connection, and the second connection are around the second emission area and the sub-area of the sub-pixel of the first pixel and the first emission area of the sub-pixel of the second pixel.

In one or more embodiments, the sub-area of the sub-pixel of the first pixel is between the second emission area of the sub-pixel of the first pixel and the first emission area of the sub-pixel of the second pixel.

In one or more embodiments, the light-emitting elements are in the sub-pixels of the first pixel and the second pixel and include first light-emitting elements and second light-emitting elements.

In one or more embodiments, the first light-emitting elements are in the second emission areas, and the second light-emitting elements are in the first emission areas, of the sub-pixels of the first pixel and the second pixel.

In one or more embodiments, the first light-emitting elements and the second light-emitting elements do not overlap the first connection and the second connection of the bank layer.

In one or more embodiments, the light-emitting elements overlap the first emission area and the second emission area and do not overlap the sub-area.

In one or more embodiments, the display device further includes: a third connection electrode partially around the second connection electrode; a fourth connection electrode facing the third connection electrode; and a fifth connection electrode facing the fourth connection electrode, wherein the light-emitting elements include a first light-emitting element between the first connection electrode and the second connection electrode, a second light-emitting element between the second connection electrode and the third connection electrode, a third light-emitting element between the third connection electrode and the fourth connection electrode, and a fourth light-emitting element between the fourth connection electrode and the fifth connection electrode.

In one or more embodiments, a display device includes: a substrate including a first sub-pixel and a second sub-pixel spaced from each other in a first direction; a bank layer above the substrate and dividing a first emission area and a second emission area of the first sub-pixel and a first emission area and a second emission area of the second sub-pixel; a first connection electrode, a second connection electrode, and a third connection electrode in the first sub-pixel and the second sub-pixel, and extending across the first emission area and the second emission area; and light-emitting elements above the substrate, and respectively between the first connection electrode and the second connection electrode and between the second connection electrode and the third connection electrode, wherein the first connection electrode, the second connection electrode, and the third connection electrode cross and overlap the bank layer.

In one or more embodiments, the bank layer is around the first emission area of the first sub-pixel and the second emission area of the second sub-pixel.

In one or more embodiments, in the first sub-pixel and the second sub-pixel, the light-emitting elements include a first light-emitting element and a second light-emitting element between the first connection electrode and the second connection electrode, and a third light-emitting element and a fourth light-emitting element between the second connection electrode and the third connection electrode.

In one or more embodiments, the first light-emitting element and the fourth light-emitting element are in the first emission area and wherein the second light-emitting element and the third light-emitting element are in the second emission area.

In one or more embodiments, the first light-emitting element and the fourth light-emitting element are adjacent to the second light-emitting element and the third light-emitting element with the bank layer therebetween.

In one or more embodiments, the display device further includes a sub-area between the first emission area of the first sub-pixel and the second emission area of the second sub-pixel, and not overlapping the bank layer and the light-emitting elements. The display device according to one or more embodiments may include emission areas of sub-pixels in which the bank layers are located adjacent to each other, thereby reducing or preventing driving defects of the sub-pixels even when light-emitting element areas in which no light-emitting element are located exist. In addition, even when a driving defect occurs in one sub-pixel, it is possible to reduce or prevent the likelihood of a dark spot being recognized due to light emitted from an adjacent sub-pixel.

However, aspects according to one or more embodiments of the present disclosure are not limited to those described above and various other aspects are incorporated herein.

### BRIEF DESCRIPTION OF THE DRAWINGS

The above and other aspects of the present disclosure will become more apparent by describing in detail embodiments thereof with reference to the attached drawings, in which:

FIG. 1 is a schematic plan view of a display device according to one or more embodiments;

FIG. 2 is a plan view showing arrangement of a plurality of wires included in a display device according to one or more embodiments;

FIG. 3 is an equivalent circuit diagram of a sub-pixel according to one or more embodiments;

FIG. 4 is a plan view illustrating pixels of a display device according to one or more embodiments;

FIG. 5 is a plan view illustrating electrodes of a display device according to one or more embodiments;

FIG. 6 is a plan view illustrating connection electrodes of a display device according to one or more embodiments;

FIG. 7 is a schematic cross-sectional view of a display device according to one or more embodiments;

FIG. 8 is a schematic perspective cutaway view of a light-emitting element according to one or more embodiments;

FIG. 9 is a plan view schematically showing electrodes, a bank layer and light-emitting elements of a display device according to one or more embodiments;

FIG. 10 is a plan view schematically showing connection electrodes, a bank layer, and light-emitting elements of display devices according to one or more embodiments;

FIG. 11 is a plan view showing a current flow of connection electrodes and light-emitting elements of display devices according to one or more embodiments;

FIG. 12 is a plan view showing a current flow of connection electrodes and light-emitting elements of display devices according to one or more embodiments;

FIG. 13 is a plan view showing connection electrodes, a bank layer, and light-emitting elements of a display device according to one or more embodiments; and

FIG. 14 is a plan view showing a current flow of connection electrodes and light-emitting elements of display devices according to one or more embodiments.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that the present disclosure will be thorough and complete, and will fully convey the scope of the present to those skilled in the art.

It will also be understood that when a layer is referred to as being “on” another layer or substrate, it can be directly on the other layer or substrate, or intervening layers may also be present. The same reference numbers indicate the same components throughout the present disclosure.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, embodiments of the present disclosure will be described with reference to the accompanying drawings.

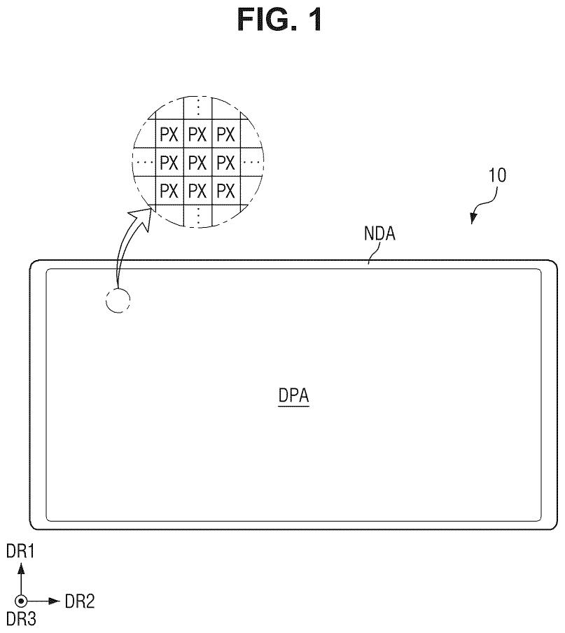

FIG. 1 is a schematic plan view of a display device according to one or more embodiments.

Referring to FIG. 1, a display device 10 displays a moving image or a still image. The display device 10 may refer to any electronic device that provides a display screen. For example, the display device 10 may include a television set, a laptop computer, a monitor, an electronic billboard, the Internet of Things (IoT) devices, a mobile phone, a smart phone, a tablet personal computer (PC), an electronic watch, a smart watch, a watch phone, a head-mounted display device, a mobile communications terminal, an electronic notebook, an electronic book, a portable multimedia player (PMP), a navigation device, a game console and a digital camera, a camcorder, etc.

The display device 10 includes a display panel for providing a display screen. Examples of the display panel may include an inorganic light-emitting diode display panel, an organic light-emitting display panel, a quantum-dot light-emitting display panel, a plasma display panel, a field emission display panel, etc. In the following description, an inorganic light-emitting diode display panel is employed as an example of the display device 10, but the present disclosure is not limited thereto. Any other display panel may be employed as long as the technical idea of the present disclosure can be equally applied.

The shape of the display device 10 may be modified in a variety of ways. For example, the display device 10 may have shapes such as a rectangle with longer lateral sides, a rectangle with longer vertical sides, a square, a quadrangle with rounded corners (vertices), other polygons, a circle, etc. The shape of a display area DPA of the display device 10 may also be similar to the overall shape of the display device 10. As shown in FIG. 1, the display device 10 has a rectangular shape with the longer sides in a second direction DR2.

The display device 10 may include a display area DPA and a non-display area NDA around an edge or periphery of the display area DPA. In the display area DPA, images can be displayed. In the non-display area NDA, images are not displayed. The display area DPA may be referred to as an active area, while the non-display area NDA may also be referred to as an inactive area. The display area DPA may generally occupy the majority of the center (or central portion) of the display device 10.

The display area DPA may include a plurality of pixels PX. The plurality of pixels PX may be arranged in a matrix. For example, the plurality of pixels PX may be arranged along rows and columns of a matrix. The shape of each pixel PX may be, but is not limited to, a rectangle or a square when viewed from the top. Each pixel may have a diamond shape having sides inclined with respect to a direction. The pixels PX may be arranged in stripes or an island pattern or a PENTILE® arrangement structure, but the present disclosure is not limited thereto. This PENTILE® arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea.

Each of the pixels PX may include at least one light-emitting element that emits light of a corresponding wavelength band to represent a color.

The non-display area NDA may be located around the display area DPA along an edge or periphery of the display area DPA. The non-display area NDA may surround the display area DPA entirely or partially. The display area DPA may have a rectangular shape, and the non-display area NDA may be adjacent to the four sides of the display area DPA. The non-display area NDA may form the bezel of the display device 10. Lines or circuit drivers included in the display device 10 may be located in each of the non-display area NDA, or external devices may be mounted.

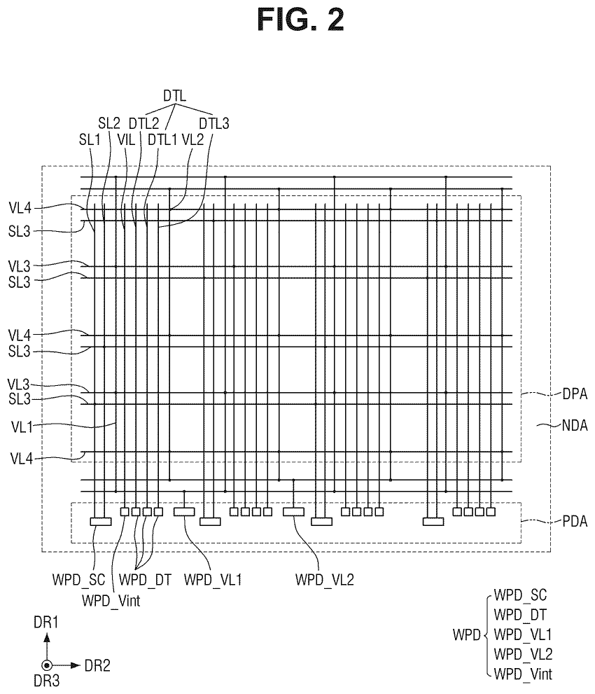

FIG. 2 is a plan view showing an arrangement of a plurality of wires included in a display device according to one or more embodiments.

Referring to FIG. 2, the display device 10 may include a plurality of lines. The display device 10 may include a plurality of scan lines SL (SL1, SL2, and SL3), a plurality of data lines DTL (DTL1, DTL2, and DTL3), initialization voltage lines VIL, and a plurality of voltage lines VL (VL1, VL2, VL3, and VL4). In FIG. 2, other lines may be further located in the display device 10.

First scan lines SL1 and second scan lines SL2 may extend in a first direction DR1. The first scan line SL1 and the second scan line SL2 may be located in a state in which they are adjacent to each other, and may be spaced from the other first scan lines SL1 and second scan lines SL2 in the second direction DR2. The first scan lines SL1 and the second scan lines SL2 may be connected to scan line pads WPD_SC connected to a scan driver. The first scan lines SL1 and the second scan lines SL2 may extend from a pad area PDA located in the non-display area NDA to the display area DPA.

A third scan line SL3 may extend in the second direction DR2, and may be spaced from the other third scan lines SL3 in the first direction DR1. One third scan line SL3 may be connected to one or more first scan lines SL1 or one or more second scan lines SL2. In one or more embodiments, the first scan line SL1 and the second scan line SL2 may be formed of a conductive layer located on a different layer from the third scan line SL3. The plurality of scan lines SL may have a mesh structure in the entirety of the display area DPA, but are not limited thereto.

In one or more embodiments, the term “connected” as used herein may mean not only that one member is connected to another member through a physical contact, but also that one member is connected to another member through yet another member. This may also be understood as one part and the other part as integral elements are connected into an integrated element via another element. Furthermore, if one element is connected to another element, this may be construed as a meaning including an electrical connection via another element in addition to a direct connection in physical contact.

The data lines DTL may extend in the first direction DR1. The data lines DTL may include first data lines DTL1, second data lines DTL2, and third data lines DTL3, and one first to third data lines DTL1, DTL2, and DTL3 form one pair and are adjacent to each other. Each of the data lines DTL1, DTL2, and DTL3 may extend from the pad area PDA located in the non-display area NDA to the display area DPA. However, the present disclosure is not limited thereto, and the plurality of data lines DTL may also be spaced from each other at equal intervals (e.g., at substantially equal intervals) between a first voltage line VL1 and a second voltage line VL2 to be described later.

The initialization voltage lines VIL may extend in the first direction DR1. The initialization voltage line VIL may be located between the data lines DTL and the first and the second scan lines SL1 and SL2. The initialization voltage lines VIL may extend from the pad area PDA located in the non-display area NDA to the display area DPA.

First voltage lines VL1 and second voltage lines VL2 extend in the first direction DR1, and third voltage lines VL3 and fourth voltage lines VL4 extend in the second direction DR2. The first voltage lines VL1 and the second voltage lines VL2 may be alternately arranged along the second direction DR2, and the third voltage lines VL3 and the fourth voltage lines VL4 may be alternately arranged along the first direction DR1. The first voltage lines VL1 and the second voltage lines VL2 may extend in the first direction DR1 to cross the display area DPA, and some of each of the third voltage lines VL3 and the fourth voltage lines VL4 may be located in the display area DPA and the others of each of the third voltage lines VL3 and the fourth voltage lines VL4 may be located in the non-display areas NDA positioned on both sides of the display area DPA in the first direction DR1. The first voltage line VL1 and the second voltage line VL2 may be formed of a conductive layer located on a different layer from the third voltage line VL3 and the fourth voltage line VL4. The first voltage line VL1 may be connected to at least one third voltage line VL3, the second voltage line VL2 may be connected to at least one fourth voltage line VL4, and the plurality of voltage lines VL may have a mesh structure in the entirety of the display area DPA. However, the present disclosure is not limited thereto.

The first scan line SL1, the second scan line SL2, the data lines DTL, the initialization voltage line VIL, the first voltage line VL1, and the second voltage line VL2 may be electrically connected to at least one line pad WPD. Each line pad WPD may be located in the non-display area NDA. In one or more embodiments, each of the line pads WPD may be located in the pad area PDA positioned on the lower side, which is the other side of the display area DPA in the first direction DR1. The first scan line SL1 and the second scan line SL2 are connected to the scan line pad WPD_SC located in the pad area PDA, and the plurality of data lines DTL are connected to the data line pads WPD_DT different from each other, respectively. The initialization voltage line VIL is connected to an initialization line pad WPD_Vint, the first voltage line VL1 is connected to a first voltage line pad WPD_VL1, and the second voltage line VL2 is connected to a second voltage line pad WPD_VL2. The external devices may be mounted on the line pads WPD. The external devices may be mounted on the line pads WPD by applying an anisotropic conductive film, ultrasonic bonding or the like. The drawing shows that each of the line pads WPD is located on the pad area PDA located on the lower side of the display area DPA, but is not limited thereto. Some of the plurality of line pads WPD may be located in any one area on the upper side or on the left and right sides of the display area DPA.

Each pixel PX or sub-pixel SPXn (n is an integer of 1 to 3) of the display device 10 includes a pixel driving circuit. The above-described lines may apply driving signals to the respective pixel driving circuits while passing through the respective pixels PX or around the respective pixels PX. The pixel driving circuit may include a transistor and a capacitor. The numbers of transistors and capacitors in each pixel driving circuit may be variously modified. According to one or more embodiments, each sub-pixel SPXn of the display device 10 may have a 3T1C structure in which the pixel driving circuit includes three transistors and one capacitor. Hereinafter, the pixel driving circuit will be described using the 3T1C structure, but the present disclosure is not limited thereto, and various other modified structures such as a 2T1C structure, a 7T1C structure, and a 6T1C structure may be applied.

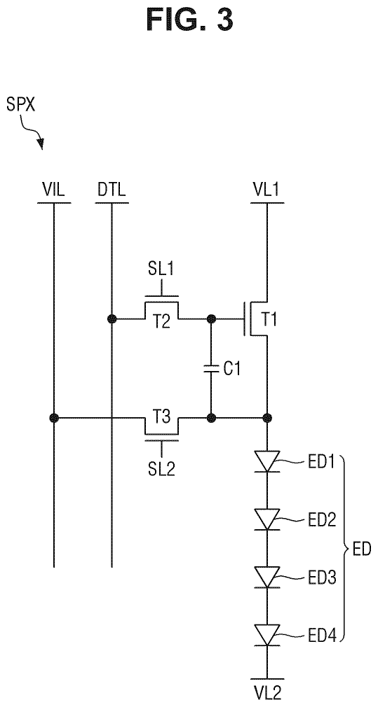

FIG. 3 is an equivalent circuit diagram of a sub-pixel according to one or more embodiments.

Referring to FIG. 3, each sub-pixel SPX of the display device 10 according to one or more embodiments includes three transistors T1, T2, and T3 and one storage capacitor C1, in addition to at least one light-emitting element ED.

The light-emitting element ED may emit light according to a current supplied through a first transistor T1. The light-emitting element ED may include a first electrode, a second electrode, and first to fourth light-emitting elements ED1, ED2, ED3 and ED4 located between the first electrode and the second electrode. The first to fourth light-emitting elements ED1, ED2, ED3 and ED4 may be connected in series. The first to fourth light-emitting elements ED1, ED2, ED3 and ED4 may receive a driving current to emit light. The light emission amount or the luminance of the light-emitting element ED may be proportional to the magnitude of the driving current. The light-emitting element ED may be an organic light-emitting diode (OLED) having an organic light-emitting layer, a quantum dot light-emitting diode (LED) including a quantum dot light-emitting layer, a micro LED, or an inorganic LED having an inorganic semiconductor.

The first electrode of the first light-emitting element ED1 may be connected to the source electrode of the first transistor T1, the drain electrode of the third transistor T3, and the second capacitor electrode of the capacitor C1. The second electrode of the first light-emitting element ED1 may be connected to the first electrode of the second light-emitting element ED2. The second light-emitting element ED2, the third light-emitting element ED3, and the fourth light-emitting element ED4 may each be connected in series. The second electrode of the fourth light-emitting element ED4 may be connected to the second voltage line VL2.

A first transistor T1 adjusts a current flowing from the first voltage line VL1, to which the first power voltage is applied, to the light-emitting diode ED according to a voltage difference between a gate electrode and the source electrode of the first transistor T1. For example, the first transistor T1 may be a driving transistor for driving the light-emitting diode ED. The gate electrode of the first transistor T1 may be connected to the source electrode of a second transistor T2, the source electrode thereof may be connected to the first electrode of the light-emitting diode ED, and the drain electrode thereof may be connected to the first voltage line VL1 to which the first power voltage is applied.

A second transistor T2 is turned on by the scan signal of a first scan line SL1 to connect a data line DTL to the gate electrode of the first transistor T1. The gate electrode of the second transistor T2 may be connected to the first scan line SL1, the source electrode thereof may be connected to the gate electrode of the first transistor T1, and the drain electrode thereof may be connected to the data line DTL.

The third transistor T3 is turned on by a scan signal of the second scan line SL2 to connect the initialization voltage line VIL to one end of the light-emitting diode ED. The gate electrode of the third transistor T3 may be connected to the second scan line SL2, the drain electrode thereof may be connected to the initialization voltage line VIL, and the source electrode thereof may be connected to one end of the light-emitting diode ED or to the source electrode of the first transistor T1.

In one or more embodiments, the source electrode and the drain electrode of each of the transistors T1, T2, and T3 are not limited to those described above, and vice versa. Further, each of the transistors T1, T2, and T3 may be formed of a thin-film transistor. In addition, in FIG. 3, each of the transistors T1, T2, and T3 has been described as being formed of an N-type metal oxide semiconductor field effect transistor (MOSFET), but is not limited thereto. For example, each of the transistors T1, T2, and T3 may be formed of a P-type MOSFET. Alternatively, some of the transistors T1, T2, and T3 may be formed of an N-type MOSFET and the others may be formed of a P-type MOSFET.

The storage capacitor C1 is formed between the gate electrode and the source electrode of the first transistor T1. The storage capacitor C1 stores a difference voltage between a gate voltage and a source voltage of the first transistor T1.

Hereinafter, a structure of one pixel PX of the display device 10 according to one or more embodiments will be described in detail additionally with reference to other drawings.

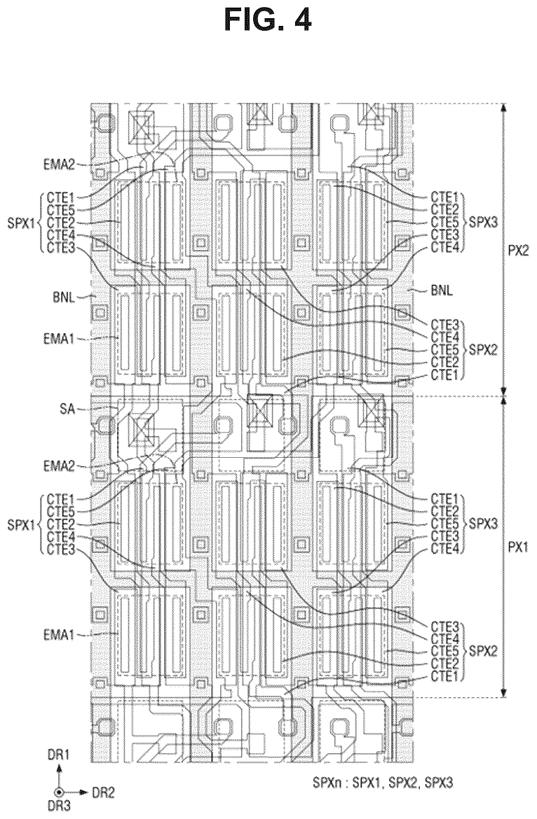

FIG. 4 is a plan view illustrating pixels of a display device according to one or more embodiments.

FIG. 4 illustrates the planar arrangement of electrodes RME (RME1 and RME2), a bank layer BNL, and connection electrodes CTE (CTE1, CTE2, CTE3, CTE4 and CTE5) located in each of the pixels PX1 and PX2 of the display device 10.

Referring to FIG. 4, the display device 10 may include a first pixel PX1 and a second pixel PX2. Each of the first pixel PX1 and the second pixel PX2 may include a plurality of sub-pixels SPXn. For example, the first pixel PX1 may include a first sub-pixel SPX1, a second sub-pixel SPX2, and a third sub-pixel SPX3, and the second pixel PX2 may include a first sub-pixel SPX1, a second sub-pixel SPX2, and a third sub-pixel SPX3.

The first sub-pixel SPX1 of each of the first pixel PX1 and the second pixel PX2 may emit light of a first color, the second sub-pixel SPX2 of each of the first pixel PX1 and the second pixel PX2 may emit light of a second color, and the third sub-pixel SPX3 of each of the first pixel PX1 and the second pixel PX2 may emit light of a third color. For example, the first color may be blue, the second color may be green, and the third color may be red. However, the present disclosure is not limited thereto, and each sub-pixel SPXn may emit light of the same color. In one or more embodiments, each sub-pixel SPXn may emit blue light. In the drawing, it is illustrated that one pixel PX includes three sub-pixels SPXn, but the present disclosure is not limited thereto, and the pixel PX may include a larger number of sub-pixels SPXn.

Each sub-pixel SPXn of the display device 10 may include a first emission area EMA1, a second emission area EMA2, and a non-emission area. Each of the first emission area EMA1 and the second emission area EMA2 may be an area in which the light-emitting elements ED is located to emit light of a specific wavelength range. The non-emission area may be a region in which the light-emitting element ED is not located and a region from which light is not emitted because light emitted from the light-emitting element ED does not reach there.

The first and second emission areas EMA1 and EMA2 may each include an area in which the light-emitting element ED is located, and an area adjacent to the light-emitting element ED to emit light emitted from the light-emitting element ED. For example, the first and second emission areas EMA1 and EMA2 may also each include an area in which light emitted from the light-emitting element ED is reflected or refracted by another member and emitted. The plurality of light-emitting elements ED may be located in each sub-pixel SPXn, and the emission area may be formed to include an area where the light-emitting elements ED are located and an area adjacent thereto.

Although it is shown in the drawing that the sub-pixels SPXn have the first and second emission areas EMA1 and EMA2 that have the same size, the present disclosure is not limited thereto. In one or more embodiments, each of the first and second emission areas EMA1 and EMA2 of each sub-pixel SPXn may have different sizes according to a color or wavelength band of light emitted from the light-emitting element ED located in each sub-pixel.

Each sub-pixel SPXn may further include a sub-area SA located in the non-emission area. The sub-area SA of the corresponding sub-pixel SPXn may be located above the second emission area EMA2 in the first direction DR1. The first emission area EMA1, the second emission area EMA2, and the sub-area SA may be alternately arranged along the first direction DR1. For example, the first emission area EMA1, the second emission area EMA2, and the sub-area SA may be alternately arranged along the first direction DR1. However, the present disclosure is not limited thereto, and in the plurality of pixels PX, the first emission area EMA1, the second emission area EMA2, and the sub-areas SA may have a different arrangement from the arrangement of FIG. 4.

Light may not be emitted from the sub-area SA because the light-emitting element ED is not located in the sub-area SA, but an electrode RME located in each sub-pixel SPXn may be partially located in the sub-area SA. The electrodes RME of each of the sub-pixels SPX1, SPX2, and SPX3 may be connected to each other and extended in the first direction DR1 in the sub-area SA. For example, in the sub-area SA located above the second emission area EMA2 of the first pixel PX1, the first and second electrodes RME1 and RME2 of each of the sub-pixels SPX1, SPX2 and SPX3 of the first pixel PX1 may be extended and connected to the first and second electrodes RME1 and RME2 of each of the sub-pixels SPX1, SPX2 and SPX3 of the second pixel PX2 located on the upper side.

The bank layer BNL may be around (e.g., may surround) the sub-pixels SPXn of each of the first pixel PX1 and the second pixel PX2, the first emission area EMA1, the second emission area EMA2, and the sub-area SA. The bank layer BNL may be located in a boundary between the sub-pixels SPXn adjacent to each other in the second direction DR2, and may be located in a boundary between the first emission area EMA1 and the second emission area EMA2 of each sub-pixel SPXn. The sub-pixels SPXn of the display device 10, the first emission area EMA1 and the second emission area EMA2 may be distinguished by the arrangement of the bank layer BNL. For example, the bank layer BNL may be around (e.g., may surround) the second emission area EMA2 of the first pixel PX1, the sub-area SA, and the first emission area EMA1 of the second pixel PX2. A detailed description thereof will be given later.

The bank layer BNL may include portions extending in the first direction DR1 and the second direction DR2 in a plan view and may be arranged in a ladder pattern over the entire surface of the display area DPA. The bank layer BNL may be located across the boundary of each of the sub-pixels SPXn arranged along the second direction DR2 to distinguish neighboring sub-pixels SPXn.

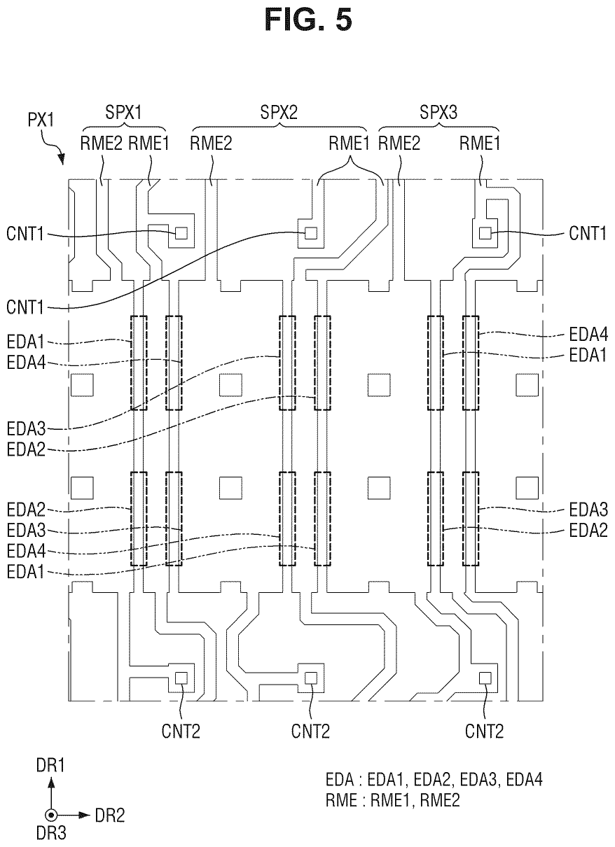

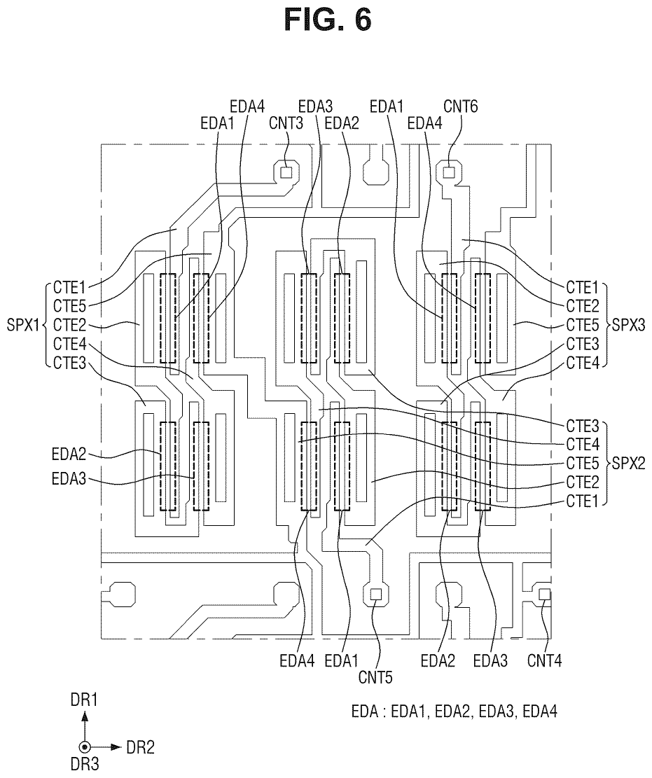

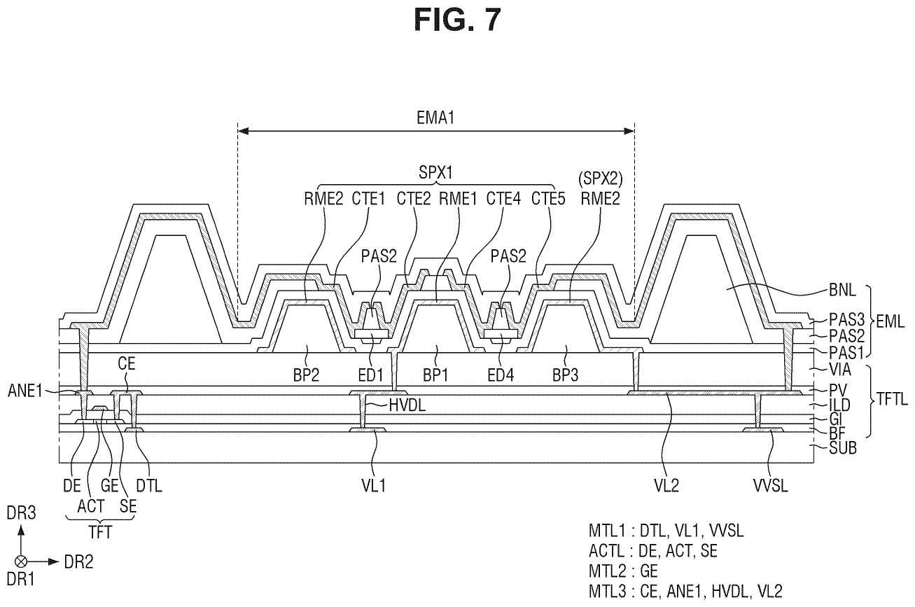

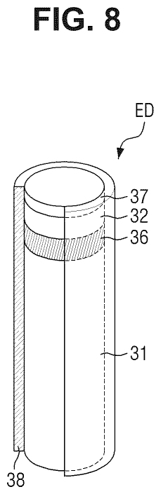

FIG. 5 is a plan view illustrating electrodes of a display device according to one or more embodiments. FIG. 6 is a plan view illustrating connection electrodes of a display device according to one or more embodiments. FIG. 7 is a schematic cross-sectional view of a display device according to one or more embodiments. FIG. 8 is a schematic perspective view of a light-emitting element according to one or more embodiments.

FIG. 5 illustrates a planar arrangement of electrodes RME (RME1 and RME2) located in the pixels PX1 and PX2 of the display device 10. FIG. 6 illustrates a planar arrangement of connection electrodes CTE (CTE1, CTE2, CTE3, CTE4 and CTE5) located in the pixels PX1 and PX2 of the display device 10.

Referring to FIGS. 5 to 8 in conjunction with FIG. 4, the display device 10 may include a substrate SUB, a thin-film transistor layer TFTL, and a light-emitting element layer EML.

The substrate SUB may be an insulating substrate. The substrate SUB may be made of an insulating material such as glass, quartz, or polymer resin. Further, the substrate SUB may be a rigid substrate, but may also be a flexible substrate which can be bent, folded and/or rolled. The substrate SUB may include a display area (‘DPA’ of FIG. 1) and a non-display area (‘NDA’ of FIG. 1) around (e.g., surrounding) the display area, and the display area DPA may include a sub-area SA which is a portion of the emission area EMA and the non-emission area.

The thin-film transistor layer TFTL may be located on the substrate SUB. The thin-film transistor layer TFTL may include a first metal layer MTL1, a buffer layer BF, an active layer ACTL, a gate insulating layer GI, a second metal layer MTL2, an interlayer insulating layer ILD, a third metal layer MTL3, a protective layer PV, and a via layer VIA.

The first metal layer MTL1 may include a data line DTL, a first voltage line VL1, and a vertical voltage line VVSL. The data line DTL may serve to transfer a data signal to a source electrode SE of the thin-film transistor TFT. The source electrode SE of the thin-film transistor TFT may be connected to the data line DTL through a connection electrode CE.

A high-potential voltage (or a first power voltage) may be applied to the first voltage line VL1 to be transmitted to the first electrode RME1. The first voltage line VL1 may be connected to a horizontal voltage line HVDL through a contact hole penetrating the buffer layer BF, the gate insulating layer GI, and the interlayer insulating layer ILD, and the horizontal voltage line HVDL may be connected to the first electrode RME1.

A low-potential voltage (or a second power voltage) may be applied to the vertical voltage line VVSL to be transmitted to the second electrode RME2. The vertical voltage line VVSL may be connected to the second electrode RME2 through a second voltage line VL2 to be described later.

The buffer layer BF may be located on the first metal layer MTL1 and the substrate SUB. The buffer layer BF may be formed on the substrate SUB to protect the thin-film transistors of the each pixel PX from moisture permeating through the substrate SUB susceptible to moisture permeation, and may perform a surface planarization function.

The active layer ACTL may be located on the buffer layer BF. The active layer ACTL may include a drain electrode DE, an active area ACT, and a source electrode SE of the thin-film transistor TFT.

The active area ACT may be located to partially overlap a gate electrode GE, which will be described later, in a thickness direction of the substrate SUB (e.g., a third direction DR3). The active layer ACTL may include polycrystalline silicon, monocrystalline silicon, oxide semiconductor, and/or the like. In one or more embodiments, the active layer ACTL may include polycrystalline silicon. The oxide semiconductor may be an oxide semiconductor containing indium (In). For example, the oxide semiconductor may be at least one of indium tin oxide (ITO), indium zinc oxide (IZO), indium gallium oxide (IGO), indium zinc tin oxide (IZTO), indium gallium tin oxide (IGTO), indium gallium zinc oxide (IGZO), and/or indium gallium zinc tin oxide (IGZTO).

Although it is illustrated in the drawing that one thin-film transistor TFT is located in the sub-pixel SPXn of the display device 10, the present disclosure is not limited thereto, and the display device 10 may include a larger number of transistors.

The gate insulating layer GI is located on the active layer ACTL and the buffer layer BF. The gate insulating layer GI may serve as a gate insulating layer of the thin-film transistor TFT. Although it is illustrated in the drawing that the gate insulating layer GI is entirely located on the buffer layer BF, the present disclosure is not limited thereto. In one or more embodiments, the gate insulating layer GI may be patterned with a gate electrode GE of the second metal layer MTL2 which will be described later to be partially located between the second metal layer MTL2 and the active layer ACTL.

The second metal layer MTL2 may be located on the gate insulating layer GI. The second metal layer MTL2 may include the gate electrode GE of the thin-film transistor TFT. The thin-film transistor TFT may be one of the first, second, and/or third transistors T1, T2, and/or T3 of FIG. 3.

The interlayer insulating layer ILD is located on the second metal layer MTL2 and the gate insulating layer GI. The interlayer insulating layer ILD serves as an insulating layer between the second metal layer MTL2 and other layers located thereon and may protect the second conductive layer MTL2.

The third metal layer MTL3 may be located on the interlayer insulating layer ILD. The third metal layer MTL3 may include a connection electrode CE, a first anode connection electrode ANE1, a horizontal voltage line HVDL, and a second voltage line VL2.

The connection electrode CE may connect the data line DTL and the source electrode SE of the active layer ACTL. The connection electrode CE may be connected to the data line DTL through a contact hole penetrating the buffer layer BF, the gate insulating layer GI, and the interlayer insulating layer ILD. In addition, the connection electrode CE may be connected to the source electrode SE of the active layer ACTL through a contact hole penetrating the gate insulating layer GI and the interlayer insulating layer ILD.

The horizontal voltage line HVDL may connect the first voltage line VL1 and the first electrode RME1. A high-potential voltage (or a first power voltage) may be applied to the horizontal voltage line HVDL from the first voltage line VL1. The horizontal voltage line HVDL may be connected to the first voltage line VL1 through a contact hole penetrating the buffer layer BF, the gate insulating layer GI, and the interlayer insulating layer ILD.

The second voltage line VL2 may connect the vertical voltage line VVSL and the second electrode RME2. A low-potential voltage (or a second power voltage) transmitted to the second electrode RME2 through the second voltage line VL2 may be applied to the vertical voltage line VVSL. The second voltage line VL2 may be connected to the vertical voltage line VVSL through a contact hole penetrating the buffer layer BF, the gate insulating layer GI, and the interlayer insulating layer ILD.

The protective layer PV may be located on the third metal layer MTL3. The protective layer PV may serve as an insulating layer between the third metal layer MTL3 and other layers and may protect the third metal layer MTL3.

The buffer layer BF, the gate insulating layer GI, the interlayer insulating layer ILD, and the protective layer PV described above may be formed of a plurality of inorganic layers stacked in an alternating manner. For example, the buffer layer BL, the gate insulating layer GI, the interlayer insulating layer ILD, and the protective layer PV may be formed as a double layer formed by stacking, or a multilayer formed by alternately stacking, inorganic layers including at least one of silicon oxide (SiOx), silicon nitride (SiNx), and/or silicon oxynitride (SiOxNy). However, the present disclosure is not limited thereto, and the buffer layer BF, the gate insulating layer GI, the interlayer insulating layer ILD, and the protective layer PV may be formed as a single inorganic layer containing the above-described insulating material. Further, in one or more embodiments, the interlayer insulating layer ILD may be made of an organic insulating material such as polyimide (PI) and/or the like.

The via layer VIA may be located on the protective layer PV in the display area DPA. The via layer VIA may include an organic insulating material, e.g., polyimide (PI), and may compensate the stepped portion formed by the conductive layers located thereunder to flatten the top surface. However, in one or more embodiments, the via layer VIA may be omitted.

The light-emitting element layer EML may be located on the via layer VIA. The light-emitting layer EML may include a plurality of electrodes RME (RME1 and RME2), a plurality of bank patterns BP1, BP2, and BP3, a bank layer BNL, and a plurality of light-emitting elements ED and a plurality of connections electrodes CTE (CTE1, CTE2, CTE3, CTE4 and CTE5). Also, the display device 10 may include a plurality of insulating layers PAS1, PAS2, and PAS3.

The plurality of bank patterns BP1, BP2, and BP3 may be directly located on the via layer VIA. The plurality of bank patterns BP1, BP2, and BP3 may include a first bank pattern BP1, a second bank pattern BP2, and a third bank pattern BP3.

The first bank pattern BP1 may be located in the first emission area EMA1 and the second emission area EMA2 of each sub-pixel SPXn. The first bank pattern BP1 may have a shape extended in the first direction DR1 and may be spaced from the second bank pattern BP2 and the third bank pattern BP3. The first bank pattern BP1 may form an island-like pattern, which has a narrow width and extends in the first direction DR1 in the first emission area EMA1 and the second emission area EMA2 of each sub-pixel SPXn, over the entire surface of the display area DPA.

The second bank pattern BP2 may be located in the first emission area EMA1 and the second emission area EMA2 of each sub-pixel SPXn and may have a shape extended in the first direction DR1. The second bank pattern BP2 may be located on one side of the first bank pattern BP1 to be spaced from the first bank pattern BP1. The second bank pattern BP2 may form an island-like pattern, which has a narrow width and extends in the first direction DR1 in the first emission area EMA1 and the second emission area EMA2 of each sub-pixel SPXn, over the entire surface of the display area DPA.

The third bank pattern BP3 may be located in the first emission area EMA1 and the second emission area EMA2 of each sub-pixel SPXn and may have a shape extended in the first direction DR1. The third bank pattern BP3 may be located on the other side of the first bank pattern BP1 to be spaced from the first bank pattern BP1. The third bank pattern BP3 may form an island-like pattern, which has a narrow width and extends in the first direction DR1 in the first emission area EMA1 and the second emission area EMA2 of each sub-pixel SPXn, over the entire surface of the display area DPA.

The first bank pattern BP1 is located at the center of the first emission area EMA1 and the second emission area EMA2, and the second bank pattern BP2 and the third bank pattern BP3 are spaced from each other with the first bank pattern BP1 interposed therebetween. For example, the second bank pattern BP2 may be located on the left side of the first bank pattern BP1, and the third bank pattern BP3 may be located on the right side of the first bank pattern BP1. The first bank pattern BP1, the second bank pattern BP2, and the third bank pattern BP3 may be alternately located along the second direction DR2. The light-emitting elements ED may be located between the first bank pattern BP1 and the second bank pattern BP2 that are spaced from each other and between the second bank pattern BP2 and the third bank pattern BP3 that are spaced from each other.

The first bank pattern BP1, the second bank pattern BP2, and the third bank pattern BP3 may have the same length in the first direction DR1, and may have the same widths measured in the second direction DR2. However, the present disclosure is not limited thereto, and the first bank pattern BP1, the second bank pattern BP2, and the third bank pattern BP3 may have different widths measured in the second direction DR2.

At least a portion of each of the bank patterns BP1, BP2, and BP3 may protrude with respect to the top surface of the via layer VIA. The protruding portion of the bank patterns BP1, BP2, and BP3 may have an inclined or curved side surface. Unlike as shown in the drawings, each of the bank patterns BP1, BP2, and BP3 may have a shape of a semi-circle in cross-sectional view. The bank patterns BP1, BP2, and BP3 may include an organic insulating material such as polyimide (PI), but is not limited thereto.

A plurality of electrodes RME of each sub-pixel SPXn of each of the pixels PX1 and PX2 may be located on the bank patterns BP1, BP2, and BP3 and the via layer VIA. The plurality of electrodes RME may include a first electrode RME1 and a second electrode RME2. The first electrode RME1 and the second electrode RME2 may extend in the first direction DR1. The first electrode RME1 of the first sub-pixel SPX1 may be located between the second electrode RME2 of the first sub-pixel SPX1 and the second electrode RME2 of the second sub-pixel SPX2.

Each of the first and second electrodes RME1 and RME2 may cover the upper surface and an inclined side surface of one of the first, second, and/or third bank patterns BP1, BP2, and/or BP3. Accordingly, each of the first and second electrodes RME1 and RME2 may reflect the light emitted from the first to fourth light-emitting elements ED1, ED2, ED3, and ED4 upwardly (in a third direction DR3).

The first and second electrodes RME1 and RME2 may be alignment electrodes that align the first to fourth light-emitting elements ED1, ED2, ED3, and ED4 during the process of fabricating the display device 10. The first electrodes RME1 may be connected to the horizontal voltage line HVDL of the third metal layer MTL3 through a first contact hole CNT1. The first electrode RME1 may receive a driving voltage or a high-potential voltage from the horizontal voltage line HVDL. The second electrode RME2 may be connected to the second voltage line VL2 of the third metal layer MTL3 through a second contact hole CNT2. The second electrode RME2 may receive a low-potential voltage from the second voltage line VL2.

Each of the electrodes RME may include a conductive material having a high reflectance. For example, the electrodes RME may include a metal such as silver (Ag), copper (Cu) and aluminum (AI), and/or may include an alloy including aluminum (Al), nickel (Ni), lanthanum (La), and/or the like, or a stack of a metal layer such as titanium (Ti), molybdenum (Mo) and niobium (Nb) and/or the alloy. In one or more embodiments, the electrodes RME may include a double layer or multilayer in which an alloy containing aluminum (Al) and at least one metal layer including titanium (Ti), molybdenum (Mo) and/or niobium (Nb) are stacked on one another.

It is, however, to be understood that the present disclosure is not limited thereto. The electrodes RME may further include a transparent conductive material. For example, each of the electrodes RME may include a material such as ITO, IZO and/or ITZO. In one or more embodiments, each of the electrodes RME1 and RME2 may have a structure in which one or more layers of a transparent conductive material and one or more metal layers having high reflectivity are stacked on one another, or may be made up of a single layer including them. For example, each of the electrodes RME may have a stack structure such as ITO/Ag/ITO/, ITO/Ag/IZO, or ITO/Ag/ITZO/IZO. The electrodes RME may be electrically connected to the light-emitting elements ED and may reflect some of the lights emitted from the light-emitting elements ED toward the upper side of the first substrate SUB (e.g., in the third direction DR3).

The first insulating layer PAS1 may be located on the front surface of the display area DPA, and may be located on the via layer VIA and the plurality of electrodes RME. The first insulating layer PAS1 may protect the plurality of electrodes RME and may insulate different electrodes RME from each other. For example, as the first insulating layer PAS1 is located to cover the electrodes RME before the bank layer BNL is formed, it is possible to reduce or prevent the likelihood of the electrode RME being damaged during the process of forming the bank layer BNL. In addition, the first insulating layer PAS1 can also reduce or prevent that the light-emitting elements ED located thereon are brought into contact with other elements and damaged.

In one or more embodiments, the first insulating layer PAS1 may have steps so that a portion of the upper surface is recessed between the electrodes RME that are spaced from one another in the second direction DR2. The light-emitting elements ED may be located at the steps of the upper surface of the first insulating layer PAS1, and space may be formed between the light-emitting elements ED and the first insulating layer PAS1.

The bank layer BNL may be located on the first insulating layer PAS1. The bank layer BNL may include portions extended in the first direction DR1 and the second direction DR2 and may be around (e.g., may surround in a plan view) each of the sub-pixels SPXn. The bank layer BNL may be around (e.g., may surround in a plan view) the first emission area EMA1, the second emission area EMA2, and the sub-area SA of each of the sub-pixels SPXn. In addition, the bank layer BNL may be around (e.g., may surround in a plan view) the outermost periphery of the display area DPA and may divide the display area DPA and the non-display area NDA. The bank layer BNL is located in the entire display area DPA to form a grid pattern, and the areas exposed by the bank layer BNL in the display area DPA may be the first emission area EMA1, the second emission area EMA2, and the sub-area SA.

The bank layer BNL may have a height longer than that of the bank patterns BP1, BP2, and BP3. In one or more embodiments, the top surface of the bank layer BNL may be similar to that of the bank patterns BP1, BP2, and BP3, and the thickness of the bank layer BNL may be equal to or greater than that of the bank patterns BP1, BP2, and BP3. The bank layer BNL may reduce or prevent the likelihood of ink overflowing to adjacent sub-pixels SPXn in an inkjet printing process during the manufacturing process of the display device 10. Similar to the bank patterns BP1, BP2, and BP3, the bank layer BNL may include an organic insulating material such as polyimide.

The plurality of light-emitting elements ED may be located in the first emission area EMA1 and the second emission area EMA2. The plurality of light-emitting elements ED may be aligned between the first electrode RME1 and the second electrode RME2. The plurality of light-emitting elements ED may be located in a light-emitting element area EDA, and may be spaced from each other in the first and second directions DR1 and DR2. The plurality of light-emitting elements ED may have a shape extended in one direction, and both ends may be located on different electrodes RME.

The plurality of light-emitting elements ED may be located on the first insulating layer PAS1. The light-emitting element ED may have a shape extending in one direction, and may be located such that the one direction of the extension is parallel to the upper surface of the substrate SUB. As will be described later, the light-emitting element ED may include a plurality of semiconductor layers located along the extended one direction, and the plurality of semiconductor layers may be sequentially located along a direction parallel to the upper surface of the substrate SUB. However, the present disclosure is not limited thereto, and when the light-emitting element ED has a different structure, the plurality of semiconductor layers may be located in a direction perpendicular to the substrate SUB.

The light-emitting elements ED located in each sub-pixel SPXn may emit light of different wavelength bands depending on a material constituting the semiconductor layer. However, the present disclosure is not limited thereto, and the light-emitting elements ED arranged in each sub-pixel SPXn may include the semiconductor layer of the same material and emit light of the same color. The light-emitting elements ED may be electrically connected to the electrode RME and the metal layers below the via layer VIA while being in contact with the connection electrodes CTE (CTE1, CTE2, CTE3, CTE4, and CTE5), and may emit light of a specific wavelength band by receiving an electrical signal.

The plurality of light-emitting elements ED may include a first light-emitting element ED1, a second light-emitting element ED2, a third light-emitting element ED3, and a fourth light-emitting element ED4. The plurality of first light-emitting elements ED1 may be located in the first light-emitting element area EDA1, the plurality of second light-emitting elements ED2 may be located in the second light-emitting element area EDA2, the plurality of third light-emitting elements ED3 may be located in the third light-emitting element area EDA3, and a plurality of fourth light-emitting elements ED4 may be located in the fourth light-emitting element area EDA4.

The first and second light-emitting element areas EDA1 and EDA2 may be located between the first electrode RME1 of the first sub-pixel SPX1 and the second electrode RME2 of the first sub-pixel SPX1. The third and fourth light-emitting element areas EDA3 and EDA4 may be located between the first electrode RME1 of the first sub-pixel SPX1 and the second electrode RME2 of the second sub-pixel SPX2.

The plurality of first to fourth light-emitting elements ED1, ED2, ED3 and ED4 may be aligned between the first electrode RME1 and the second electrode RME2 by the electric field formed by an alignment signal applied to the first electrode RME1 and the second electrode RME2. For example, the plurality of first to fourth light-emitting elements ED1, ED2, ED3, and ED4 may be sprayed onto the first and second electrodes RME1 and RME2 through an inkjet printing process, and the plurality of first to fourth light-emitting elements ED1, ED2, ED3 and ED4 dispersed in an ink may be aligned by receiving a dielectrophoresis force by an electric field formed between the first and second electrodes RME1 and RME2. Accordingly, the plurality of first to fourth light-emitting elements ED1, ED2, ED3, and ED4 may be aligned along the second direction DR2 between the first and second electrodes RME1 and RME2.

The second insulating layer PAS2 may be located on the plurality of light-emitting elements ED, the first insulating layer PAS1, and the bank layer BNL. The second insulating layer PAS2 extends in the first direction DR1 between the bank patterns BP1, BP2, and BP3 and includes a pattern portion located on the plurality of light-emitting elements ED. The pattern portion may be located to partially cover an outer surface (e.g., an outer peripheral or circumferential surface) of the light-emitting element ED, and both sides or both ends of the light-emitting element ED may not be covered. The pattern portion may form a linear or island-shaped pattern in each sub-pixel SPXn in a plan view. The pattern portion of the second insulating layer PAS2 may protect the light-emitting elements ED and, at the same time, fix the light-emitting elements ED in a manufacturing process of the display device 10. In addition, the second insulating layer PAS2 may be located to fill a space between the light-emitting element ED and the first insulating layer PAS1 therebelow. Also, a portion of the second insulating layer PAS2 may be located on the upper portion of the bank layer BNL and in the sub-areas SA.

The plurality of connection electrodes CTE (CTE1, CTE2, CTE3, CTE4 and CTE5) may be located on the first insulating layer PAS1, the second insulating layer PAS2, the plurality of electrodes RME, and bank patterns BP1, BP2, and BP3. Each of the plurality of connection electrodes CTE may have a shape extending in one direction and may be spaced from each other. Each of the connection electrodes CTE may be in contact with the light-emitting element ED and may be electrically connected to the third metal layer.

The plurality of connection electrodes CTE may include a first connection electrode CTE1, a second connection electrode CTE2, a third connection electrode CTE3, a fourth connection electrode CTE4, and a fifth connection electrode CTE5.

The first connection electrode CTE1 of the first sub-pixel SPX1 may be located on the first electrode RME1 of the first sub-pixel SPX1 and may be connected to the first anode connection electrode ANE1 of the third metal layer MTL3 through a third contact hole CNT3. The first connection electrode CTE1 may be connected between the first anode connection electrode ANE1 and one end of the plurality of first light-emitting elements ED1. The first connection electrode CTE1 may receive a driving current passing through the thin-film transistor TFT. The first connection electrode CTE1 may supply a driving current to the plurality of first light-emitting elements ED1 of the first sub-pixel SPX1. The first connection electrode CTE1 may correspond to the anode electrode of the plurality of first light-emitting elements ED1, but is not limited thereto.

The second connection electrode CTE2 may be located on and overlap the first and second electrodes RME1 and RME2. A first portion of the second connection electrode CTE2 may be located on the second electrode RME2 of the first sub-pixel SPX1 and extend in the first direction DR1. A second portion of the second connection electrode CTE2 may extend from a lower side of the first portion and may be located on the first electrode RME1 of the first sub-pixel SPX1.

The second connection electrode CTE2 may be connected between the other end of the plurality of first light-emitting elements ED1 and one end of the plurality of second light-emitting elements ED2. The second connection electrode CTE2 may correspond to the cathode electrode of the plurality of first light-emitting elements ED1, but is not limited thereto. The second connection electrode CTE2 may correspond to the anode electrode of the plurality of second light-emitting elements ED2, but is not limited thereto.

The third connection electrode CTE3 may be located on and overlap the first electrode RME1 and the second electrode RME2. A first portion of the third connection electrode CTE3 may be located on the second electrode RME2 of the first sub-pixel SPX1 and extend in the first direction DR1. A second portion of the third connection electrode CTE3 may be located on the first electrode RME1 of the first sub-pixel SPX1 and may be located to the right of the first portion.

The third connection electrode CTE3 may be connected between the other end of the plurality of second light-emitting elements ED2 and one end of the plurality of third light-emitting elements ED3. The third connection electrode CTE3 may correspond to the cathode electrode of the plurality of second light-emitting elements ED2 and correspond to the anode electrode of the plurality of third light-emitting elements ED3, but is not limited thereto.

The fourth connection electrode CTE4 may be located on and overlap the first electrode RME1 of the first sub-pixel SPX1 and the second electrode RME2 of the second sub-pixel SPX2. A first portion of the fourth connection electrode CTE4 may be located on the second electrode RME2 of the second sub-pixel SPX2 and extend in the first direction DR1. A second portion of the fourth connection electrode CTE4 may extend from the upper side (the first direction DR1) of the first portion and may be located on the first electrode RME1 of the first sub-pixel SPX1.

The fourth connection electrode CTE4 may be connected between the other end of the plurality of third light-emitting elements ED3 and one end of the plurality of fourth light-emitting elements ED4. The fourth connection electrode CTE4 may correspond to the cathode electrode of the plurality of third light-emitting elements ED3 and may correspond to the anode electrode of the plurality of fourth light-emitting elements ED4, but is not limited thereto.

The fifth connection electrode CTE5 may be connected between the other end of the plurality of fourth light-emitting elements ED4 and the second voltage line VL2. The fifth connection electrode CTE5 may be located on the second electrode RME2 of the second sub-pixel SPX2 and extend in the first direction DR1. The fifth connection electrode CTE5 may be connected to the second voltage line VL2 of the third metal layer MTL3 through a fourth contact hole CNT4. The fifth connection electrode CTE5 may correspond to the cathode electrode of the plurality of fourth light-emitting elements ED4. The fifth connection electrode CTE5 may receive a low-potential voltage through the second voltage line VL2. The fifth connection electrodes CTE5 of the first to third sub-pixels SPX1, SPX2 and SPX3 may be integrally formed, but is not limited thereto.

In the second sub-pixel SPX2, the first connection electrode CTE1 may be located on the first electrode RME1 of the second sub-pixel SPX2, and may be connected to the first anode connection electrode (e.g., the first anode connection electrode ANE1 located in the second sub-pixel SPX2) of the third metal layer MTL3 through a fifth contact hole CNT5. The first connection electrode CTE1 may be connected between the first anode connection electrode and one end of the plurality of first light-emitting elements ED1. The first connection electrode CTE1 may receive a driving current passing through the thin-film transistor TFT. The first connection electrode CTE1 may supply the driving current to the plurality of first light-emitting elements ED1 of the second sub-pixel SPX2.

In the third sub-pixel SPX3, the first connection electrode CTE1 may be located on the first electrode RME1 of the third sub-pixel SPX3, and may be connected to the first anode connection electrode (e.g., the first anode connection electrode ANE1 located in the third sub-pixel SPX3) of the third metal layer MTL3 through a sixth contact hole CNT6. The first connection electrode CTE1 may be connected between the first anode connection electrode and one end of the plurality of first light-emitting elements ED1. The first connection electrode CTE1 may receive a driving current passing through the thin-film transistor TFT. The first connection electrode CTE1 may supply the driving current to the plurality of first light-emitting elements ED1 of the third sub-pixel SPX3.

The plurality of connection electrodes CTE may include a conductive material. For example, the connection electrodes CTE may include ITO, IZO, ITZO, aluminum (Al), etc. For example, the connection electrodes CTE may include a transparent conductive material, and lights emitted from the light-emitting elements ED may transmit the connection electrodes CTE to exit.

The third insulating layer PAS3 is located on the plurality of connection electrodes CTE and the second insulating layer PAS2. The third insulating layer PAS3 may be located entirely on the second insulating layer PAS2 to cover the plurality of connection electrodes CTE. The third insulating layer PAS3 may be located entirely on the via layer VIA. The third insulating layer PAS3 may insulate the plurality of connection electrodes CTE from each other so that they are not in contact with each other.

Each of the above-described first insulating layer PAS1, second insulating layer PAS2, and third insulating layer PAS3 may include an inorganic insulating material and/or an organic insulating material. For example, each of the first insulating layer PAS1, the second insulating layer PAS2 and the third insulating layer PAS3 may include an inorganic insulating material, or the first insulating layer PAS1 and the third insulating layer PAS3 may include an inorganic insulating material while the second insulating layer PAS2 may include an organic insulating material. Each of the first insulating layer PAS1, the second insulating layer PAS2, and the third insulating layer PAS3 or at least one of the first insulating layer PAS1, the second insulating layer PAS2, and/or the third insulating layer PAS3 may be formed in a structure in which insulating layers are alternately or repeatedly stacked on one another.

Each of the first insulating layer PAS1, the second insulating layer PAS2, and the third insulating layer PAS3 may include at least one of silicon oxide (SiOx), silicon nitride (SiNx), and/or silicon oxynitride (SiOxNy). The first insulating layer PAS1, the second insulating layer PAS2, and the third insulating layer PAS3 may include the same material. Alternatively, some of the first insulating layer PAS1, the second insulating layer PAS2 and the third insulating layer PAS3 may include the same material while the other(s) may include different material(s), or they may include of different materials.

Referring to FIG. 8, the light-emitting element ED is a particulate element, and may have a rod-like or cylindrical shape having a suitable aspect ratio (e.g., a predetermined aspect ratio). The light-emitting elements ED may have a size of a nanometer scale (from 1 nm to 1 μm) to a micrometer scale (from 1 μm to 1 mm). According to one or more embodiments, both of the diameter and length of the light-emitting diode ED may be in nanometer scales or micrometer scales. In one or more embodiments, the diameter of the light-emitting diode ED may be in a nanometer scale, while the length of the light-emitting diode ED may be in a micrometer scale. In one or more embodiments, the diameter and/or length of some of the light-emitting diodes ED may be in nanometer scales, while the diameter and/or length of some other ones of the light-emitting diodes ED may be in micrometer scales.

According to one or more embodiments of the present disclosure, the light-emitting element ED may be an inorganic light-emitting diode. For example, the light-emitting element ED may include semiconductor layers doped with impurities of a conductive type (e.g., p-type or n-type). The semiconductor layers may emit light of a certain wavelength band by transmitting an electrical signal applied from an external power source.

The light-emitting element ED according to one or more embodiments may include a first semiconductor layer 31, a light-emitting layer 36, a second semiconductor layer 32, and an electrode layer 37 sequentially stacked in the longitudinal direction. The light-emitting element ED may further include an insulating layer 38 around (e.g., surrounding) outer surfaces (e.g., outer peripheral or circumferential surfaces) of the first semiconductor layer 31, the second semiconductor layer 32, and the light-emitting layer 36.

The first semiconductor layer 31 may be an n-type semiconductor. When the light-emitting element ED emits light of a blue wavelength band, the first semiconductor layer 31 may include a semiconductor material having a composition ratio of AlxGayIn(1-x-y)N (where 0≤x≤1, 0≤y≤1, and 0≤x+y≤1). For example, it may be at least one of n-type doped AlGaInN, GaN, AlGaN, InGaN, AlN, and/or InN. The first semiconductor layer 31 may be doped with an n-type dopant, and the n-type dopant may be Si, Ge, Sn, Se, etc. For example, the first semiconductor layer 31 may be n-GaN doped with n-type Si. The length of the first semiconductor layer 31 may range, but is not limited to, from about 1.5 μm to 5 μm.

The second semiconductor layer 32 is located on the light-emitting layer 36 which will be described later. The second semiconductor layer 32 may be a p-type semiconductor. When the light-emitting element ED emits light of a blue or green wavelength band, the second semiconductor layer 32 may include a semiconductor material having a composition ratio of AlxGayIn(1-x-y)N (where 0≤x≤1, 0≤y≤1, and 0≤x+y≤1). For example, it may be at least one of p-type doped AlGaInN, GaN, AlGaN, InGaN, AlN, and/or InN. The second semiconductor layer 32 may be doped with an p-type dopant, and the p-type dopant may be Mg, Zn, Ca, Ba, etc. For example, second semiconductor layer 32 may be p-GaN doped with p-type Mg. The length of the second semiconductor layer 32 may range, but is not limited to, from about 0.05 μm to 0.10 μm.

Although it is illustrated in the drawing that the first semiconductor layer 31 and the second semiconductor layer 32 are configured as one layer, the present disclosure is not limited thereto. Depending on the material of the light-emitting layer 36, the first semiconductor layer 31 and the second semiconductor layer 32 may further include a larger number of layers, such as a cladding layer or a tensile strain barrier reducing (TSBR) layer.

The light-emitting layer 36 is located between the first semiconductor layer 31 and the second semiconductor layer 32. The light-emitting layer 36 may include a material having a single or multiple quantum well structure. When the light-emitting layer 36 includes a material having a multiple quantum well structure, a plurality of quantum layers and well layers may be stacked alternately. The light-emitting layer 36 may emit light by coupling of electron-hole pairs according to an electrical signal applied through the first semiconductor layer 31 and the second semiconductor layer 32. When the light-emitting layer 36 emits light in a blue wavelength band, the light-emitting layer 36 may include a material such as AlGaN or AlGaInN. For example, when the light-emitting layer 36 has a structure in which quantum layers and well layers are alternately stacked in a multiple quantum well structure, the quantum layer may include a material such as AlGaN and/or AlGaInN, and the well layer may include a material such as GaN and/or AlInN. For example, as described above, the light-emitting layer 36 may include AlGaInN as a quantum layer and AlInN as a well layer, and the light-emitting layer 36 may emit blue light having a central wavelength band of about 450 nm to about 495 nm.

However, the present disclosure is not limited thereto, and the light-emitting layer 36 may have a structure in which semiconductor materials having large band gap energy and semiconductor materials having small band gap energy are alternately stacked, and may include other Group III to Group V semiconductor materials according to the wavelength band of the emitted light. The light emitted by the light-emitting layer 36 is not limited to light of a blue wavelength band, but may also emit light of a red or green wavelength band in some cases. The length of the light-emitting layer 36 may have a range of about 0.05 μm to about 0.10 μm, but is not limited thereto.

In one or more embodiments, light emitted from the light-emitting layer 36 may be emitted to both side surfaces as well as the outer surface of the light-emitting element ED in the longitudinal direction. The directionality of light emitted from the light-emitting layer 36 is not limited to one direction.

The electrode layer 37 may be an ohmic contact electrode. However, the present disclosure is not limited thereto, and it may be a Schottky contact electrode. The light-emitting element ED may include at least one electrode layer 37. Although FIG. 8 illustrates that the light-emitting element ED includes one electrode layer 37, the present disclosure is not limited thereto. In some cases, the light-emitting element ED may include a larger number of electrode layers 37 or may be omitted. The following description of the light-emitting element ED may be equally applied even if the number of electrode layers 37 is different or further includes other structures.

In the display device 10 according to one or more embodiments, when the light-emitting element ED is electrically connected to an electrode or a contact electrode, the electrode layer 37 may reduce the resistance between the light-emitting element ED and the electrode or contact electrode. The electrode layer 37 may include a conductive metal. For example, the electrode layer 37 may include at least one of aluminum (AI), titanium (Ti), indium (In), gold (Au), silver (Ag), ITO, IZO, and/or ITZO. Further, the electrode layer 37 may include an n-type or p-type doped semiconductor material. The electrode layer 37 may include the same material or may include different materials, but is not limited thereto.

The insulating layer 38 is arranged to be around (e.g., to surround) the outer surfaces (e.g., the outer peripheral or circumferential surfaces) of the plurality of semiconductor layers and electrode layers described above. For example, the insulating layer 38 may be arranged to be around (to surround) the outer surface (e.g., the outer peripheral or circumferential surface) of at least the light-emitting layer 36, and the light-emitting element ED may be elongated in one direction. The insulating layer 38 may function to protect the members. The insulating layer 38 may be formed to be around (e.g., to surround) side surfaces of the members to expose both ends of the light-emitting element ED in the longitudinal direction.

Although it is illustrated in the drawing that the insulating layer 38 extends in the longitudinal direction of the light-emitting element ED to cover a region from the first semiconductor layer 31 to the side surface of the electrode layer 37, the present disclosure is not limited thereto. The insulating layer 38 may include the light-emitting layer 36 to cover only the outer surfaces (e.g., the outer peripheral or circumferential surfaces) of some semiconductor layers, or may cover only a portion of the outer surface (e.g., the outer peripheral or circumferential surface) of the electrode layer 37 to partially expose the outer surface (e.g., the outer peripheral or circumferential surface) of each electrode layer 37. Further, in cross-sectional view, the insulating layer 38 may have a top surface, which is rounded in a region adjacent to at least one end of the light-emitting element ED. The thickness of the insulating layer 38 may have a range of about 10 nm to about 1.0 μm, but is not limited thereto. In one or more embodiments, the thickness of the insulating layer 38 may be about 40 nm.

The insulating layer 38 may include a material having insulating properties, such as silicon oxide (SiOx), silicon nitride (SiNx), silicon oxynitride (SiOxNy), aluminum nitride (AlN), and/or aluminum oxide (Al₂O₃). Although it is shown in the drawing that the insulating layer 38 is formed as a single layer, the present disclosure is not limited thereto. In one or more embodiments, the insulating layer 38 may be formed in a multilayer structure in which a plurality of layers are stacked. Accordingly, it is possible to reduce or prevent the likelihood of an electrical short circuit that may occur when the light-emitting layer 36 is in direct contact with the electrode through which the electrical signal is transmitted to the light-emitting element ED. In addition, because the insulating layer 38 includes the light-emitting layer 36 to protect the outer surface (e.g., the outer peripheral or circumferential surface) of the light-emitting element ED, it is possible to prevent or reduce degradation in light emission efficiency.

Further, the insulating layer 38 may have an outer surface (e.g., an outer peripheral or circumferential surface) which is surface-treated. The light-emitting elements ED may be aligned in such a way of spraying the ink in which the light-emitting elements ED are dispersed on the electrodes. Here, the surface of the insulating layer 38 may be treated in a hydrophobic or hydrophilic manner to keep the light-emitting elements ED in a dispersed state without aggregation with other light-emitting elements ED adjacent in the ink. For example, the insulating layer 38 may be surface-treated on the outer surface (e.g., the outer peripheral or circumferential surface) thereof with a material such as stearic acid and 2,3-naphthalene dicarboxylic acid.

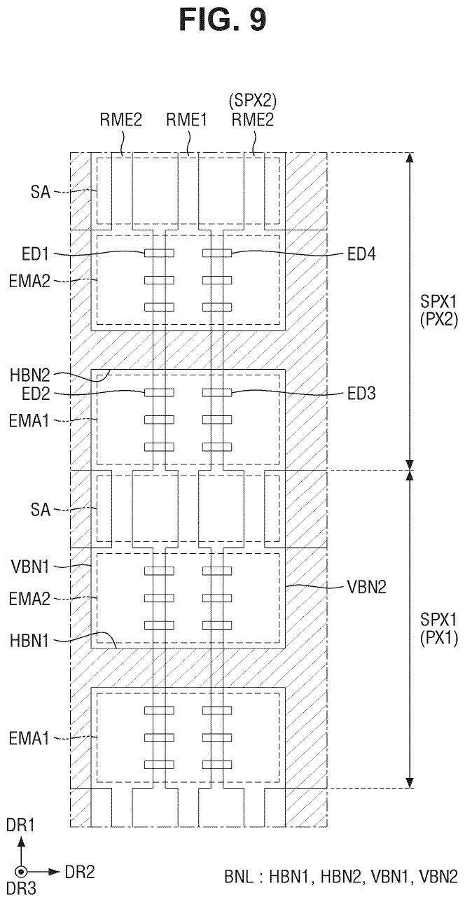

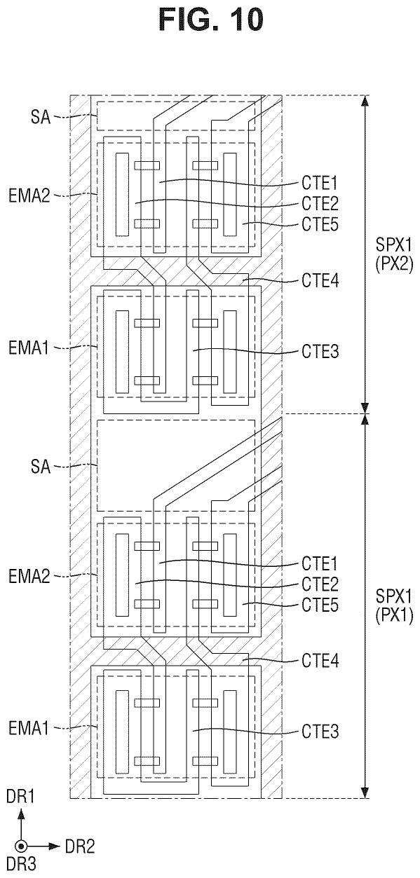

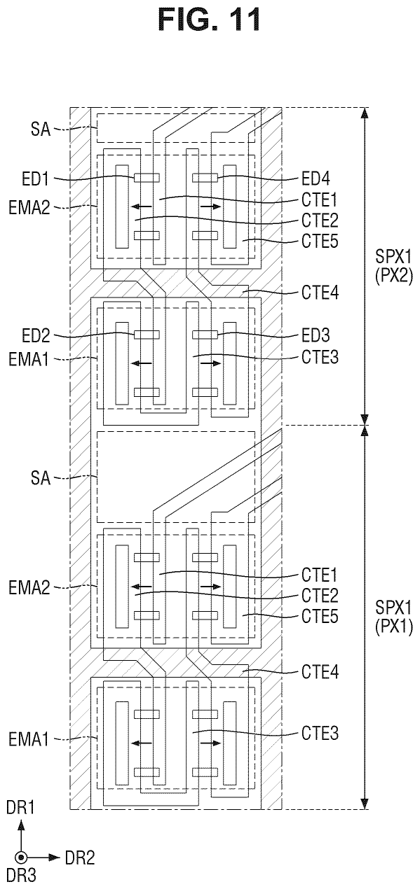

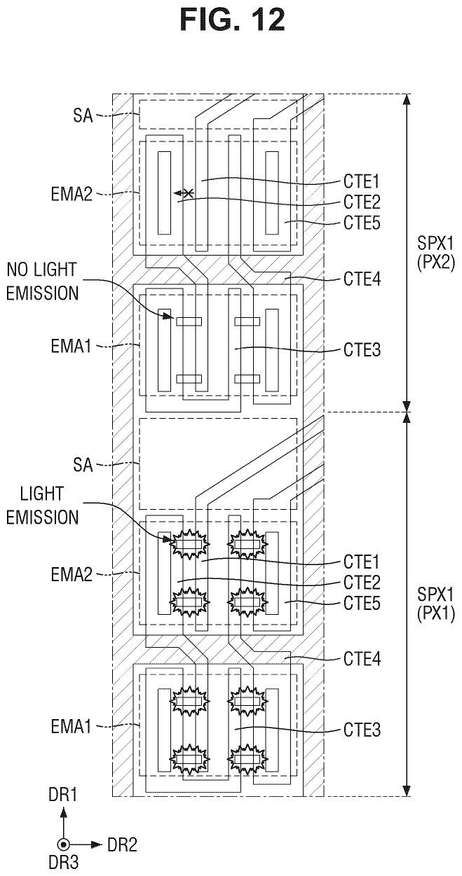

FIG. 9 is a plan view schematically showing electrodes, a bank layer, and light-emitting elements of a display device according to one or more embodiments. FIG. 10 is a plan view schematically showing connection electrodes, a bank layer, and light-emitting elements of display devices according to one or more embodiments. FIG. 11 is a plan view showing a current flow of connection electrodes and light-emitting elements of display devices according to one or more embodiments. FIG. 12 is a plan view showing a current flow of connection electrodes and light-emitting elements of display devices according to one or more embodiments.

FIGS. 9 and 10 each show the first sub-pixel SPX1 of the first pixel PX1 and the first sub-pixel SPX1 of the second pixel PX2.

Referring to FIGS. 9 and 10, the first pixel PX1 and the second pixel PX2 may be located along the first direction DR1. The first sub-pixel SPX1 of the first pixel PX1 and the first sub-pixel SPX1 of the second pixel PX2 may be located adjacent to each other in the first direction DR1. For example, the first sub-pixel SPX1 of the second pixel PX2 may be located above the first sub-pixel SPX1 of the first pixel PX1.

The first electrode RME1 and the second electrode RME2 may extend in the first direction DR1, to respectively form the first sub-pixel SPX1 of the first pixel PX1 and the first sub-pixel SPX1 of the second pixel PX2.

The bank layer BNL may be arranged in a lattice shape (or matrix shape), and divide the first emission area EMA1, the second emission area EMA2, and the sub-area SA in each of the first sub-pixel SPX1 of the first pixel PX1 and the first sub-pixel SPX1 of the second pixel PX2.

The bank layer BNL may include a first extension VBN1 and a second extension VBN2 extending in the first direction DR1 and spaced from each other, and the first extension VBN1 may include a first connection HBN1 and a second connection HBN2 connecting the first extension VBN1 and the second extension VBN2.

The first extension VBN1 and the second extension VBN2 may extend in the first direction DR1 and may be spaced from each other in the second direction DR2. The first extension VBN1 may be located on one side of the first sub-pixel SPX1 of the first pixel PX1 and the first sub-pixel SPX1 of the second pixel PX2, and the second extension VBN2 may be located on the other side of the first sub-pixel SPX1 of the first pixel PX1 and the first sub-pixel SPX1 of the second pixel PX2. For example, the first extension VBN1 may be located on the left side of the first sub-pixel SPX1 of the first pixel PX1 and the first sub-pixel SPX1 of the second pixel PX2, and the second extension VBN2 may be located on the right side of the first sub-pixel SPX1 of the first pixel PX1 and the first sub-pixel SPX1 of the second pixel PX2.

The first connection HBN1 and the second connection HBN2 may extend in the second direction DR2 to connect the first extension VBN1 and the second extension VBN2. The first connection HBN1 and the second connection HBN2 may be spaced from each other in the first direction DR1. The first connection HBN1 may be located on the first sub-pixel SPX1 of the first pixel PX1, and the second connection HBN2 may be located on the first sub-pixel SPX1 of the second pixel PX2. The first connection HBN1 and the second connection HBN2 may overlap and cross the first electrode RME1 and the second electrode RME2, respectively.

The bank layer BNL may be around (e.g., may surround in a plan view) the first emission area EMA1, the second emission area EMA2, and the sub-area SA through the first extension VBN1, the second extension VBN2, the first connection HBN1, and the second connection HBN2. For example, the first sub-pixel SPX1 of the first pixel PX1 may be divided into the first emission area EMA1 and the second emission area EMA2 by the first extension VBN1, the second extension VBN2, and the first connection HBN1. The first emission area EMA1 of the first sub-pixel SPX1 of the first pixel PX1 may be located below (e.g., in a direction opposite to the first direction DR1) the first connection HBN1, and the second emission area EMA2 of the first sub-pixel SPX1 of the first pixel PX1 may be located above (e.g., in the first direction DR1) the first connection HBN1. The first connection HBN1 of the bank layer BNL may be located between the first emission area EMA1 and the second emission area EMA2 of the first sub-pixel SPX1 of the first pixel PX1.

The first sub-pixel SPX1 of the second pixel PX2 may be divided into the first emission area EMA1 and the second emission area EMA2 by the first extension VBN1, the second extension VBN2, and the second connection HBN2. The first emission area EMA1 of the first sub-pixel SPX1 of the second pixel PX2 may be located below (e.g., in a direction opposite to the first direction DR1) the second connection HBN2, and the second emission area EMA2 of the first sub-pixel SPX1 of the second pixel PX2 may be located above (e.g., in the first direction DR1) the second connection HBN2. The second connection HBN2 of the bank layer BNL may be located between the first emission area EMA1 and the second emission area EMA2 of the first sub-pixel SPX1 of the second pixel PX2.

The bank layer BNL may be around (e.g., may surround in a plan view) the second emission area EMA2 of the first sub-pixel SPX1 of the first pixel PX1 and the first emission area EMA1 of the first sub-pixel SPX1 of the second pixel PX2. The first extension VBN1, the second extension VBN2, the first connection HBN1, and the second connection HBN2 of the bank layer BNL may be around (e.g., may surround in a plan view) the second emission area EMA2 and the sub-area SA of the first sub-pixel SPX1 of the first pixel PX1, and the first emission area EMA1 of the first sub-pixel SPX1 of the second pixel PX2. The sub-area SA of the first sub-pixel SPX1 of the first pixel PX1 may be located between the second emission area EMA2 of the first sub-pixel SPX1 of the first pixel PX1 and the first emission area EMA1 of the first sub-pixel SPX1 of the second pixel PX2.

The plurality of light-emitting elements ED may be located in the first sub-pixel SPX1 of the first pixel PX1 and the first sub-pixel SPX1 of the second pixel PX2.

In the first sub-pixel SPX1 of the first pixel PX1, the plurality of light-emitting elements ED may include the first light-emitting element ED1 and the fourth light-emitting element ED4 located in the second emission area EMA2 and a second light-emitting element ED2 and a third light-emitting element ED3 located in the first emission area EMA1. The first to fourth light-emitting elements ED1, ED2, ED3, and ED4 might not overlap the bank layer BNL. For example, the first to first to fourth light-emitting elements ED1, ED2, ED3, and ED4 might not overlap the first connection HBN1 crossing the first sub-pixel SPX1 in the second direction DR2. The first light-emitting element ED1 and the fourth light-emitting element ED4 may be located on one side (e.g., in the first direction DR1) with respect to the first connection HBN1, and the second light-emitting element ED2 and the third light-emitting element ED3 may be located on the other side (e.g., in a direction opposite to the first direction DR1) with respect to the first connection HBN1.

In the first sub-pixel SPX1 of the second pixel PX2, the plurality of light-emitting elements ED may include the first light-emitting element ED1 and the fourth light-emitting element ED4 located in the second emission area EMA2, and may include a second light-emitting element ED2 and a third light-emitting element ED3 located in the first emission area EMA1. The first to fourth light-emitting elements ED1, ED2, ED3, and ED4 might not overlap the bank layer BNL. For example, the first to first to fourth light-emitting elements ED1, ED2, ED3, and ED4 might not overlap the second connection HBN2 crossing the first sub-pixel SPX1 in the second direction DR2. The first light-emitting element ED1 and the fourth light-emitting element ED4 may be located on one side (e.g., in the first direction DR1) with respect to the second connection HBN2, and the second light-emitting element ED2 and the third light-emitting element ED3 may be located on the other side (e.g., in a direction opposite to the first direction DR1) with respect to the second connection HBN2.

The bank layer BNL may be around (e.g., may surround in a plan view) the first light-emitting element ED1 and the fourth light-emitting element ED4 of the first sub-pixel SPX1 of the first pixel PX1, and the second light-emitting element ED2 and the third light-emitting element ED3 of the first sub-pixel SPX1 of the second pixel PX2. For example, the first extension VBN1, the second extension VBN2, the first connection HBN1, and the second connection HBN2 of the bank layer BNL may be around (e.g., may surround in a plan view) the first light-emitting element ED1 and fourth light-emitting element ED4 of the first sub-pixel SPX1 of the first pixel PX1, and the second light-emitting element ED2 and the third light-emitting element ED3 of first sub-pixel SPX1 of second pixel PX2.

A plurality of connection electrodes CTE may be located on the first sub-pixel SPX1 of the first pixel PX1 and the first sub-pixel SPX1 of the second pixel PX2. A first connection electrode CTE1, a second connection electrode CTE2, a third connection electrode CTE3, a fourth connection electrode CTE4, and a fifth connection electrode CTE5 may be located in each of the first sub-pixel SPX1 of the first pixel PX1 and the first sub-pixel SPX1 of the second pixel PX2.

In the first sub-pixel SPX1 of the first pixel PX1, the first connection electrode CTE1 may be located on the upper side (e.g., in the first direction DR1) with respect to the first connection HBN1 of the bank layer BNL. The first connection electrode CTE1 may not overlap the first connection HBN1 of the bank layer BNL. The second connection electrode CTE2 may extend in the first direction DR1 to cross and overlap the first connection HBN1 of the bank layer BNL. The third connection electrode CTE3 may be located on the lower side (e.g., in a direction opposite to the first direction DR1) with respect to the first connection HBN1 of the bank layer BNL. The third connection electrode CTE3 may not overlap the first connection HBN1 of the bank layer BNL. The fourth connection electrode CTE4 may extend in the first direction DR1 to cross and overlap the first connection HBN1 of the bank layer BNL. The fifth connection electrode CTE5 may be located on the upper side (e.g., in the first direction DR1) with respect to the first connection HBN1 of the bank layer BNL. The fifth connection electrode CTE5 may not overlap the first connection HBN1 of the bank layer BNL.

In the first sub-pixel SPX1 of the second pixel PX2, the first connection electrode CTE1 may be located on the upper side (e.g., in the first direction DR1) with respect to the second connection HBN2 of the bank layer BNL. The first connection electrode CTE1 may not overlap the second connection HBN2 of the bank layer BNL. The second connection electrode CTE2 may extend in the first direction DR1 to cross and overlap the second connection HBN2 of the bank layer BNL. The third connection electrode CTE3 may be located on the lower side (e.g., in a direction opposite to the first direction DR1) with respect to second connection HBN2 of the bank layer BNL. The third connection electrode CTE3 may not overlap the second connection HBN2 of the bank layer BNL. The fourth connection electrode CTE4 may extend in the first direction DR1 to cross and overlap the second connection HBN2 of the bank layer BNL. The fifth connection electrode CTE5 may be located on the upper side (e.g., in the first direction DR1) with respect to the second connection HBN2 of the bank layer BNL. The fifth connection electrode CTE5 may not overlap second connection HBN2 of the bank layer BNL.

The bank layer BNL may be around (e.g., may surround in a plan view) the first connection electrode CTE1 of the first sub-pixel SPX1 of the first pixel PX1, portion of the second connection electrode CTE2, portion of the fourth connection electrode CTE4, and the fifth connection electrode CTE5. For example, the first extension VBN1, the second extension VBN2, the first connection HBN1, and the second connection HBN2 of the bank layer BNL may be around (e.g., may surround in a plan view) the first connection electrode CTE1, portion of the second connection electrode CTE2, portion of the fourth connection electrode CTE4, and fifth connection electrode CTE5 of the first sub-pixel SPX1 of the first pixel PX1.

In addition, the bank layer BNL may be around (e.g., may surround in a plan view) a portion of the second connection electrode CTE2, the third connection electrode CTE3, and a portion of the fourth connection electrode CTE4 of the first sub-pixel SPX1 of the second pixel PX2. For example, the first extension VBN1, the second extension VBN2, the first connection HBN1, and the second connection HBN2 of the bank layer BNL may be around (e.g., may surround in a plan view) a portion of the second connection electrode CTE2, the third connection electrode CTE3, and a portion of the fourth connection electrode CTE4 of the first sub-pixel SPX1 of the second pixel PX2.

In the display device 10 according to one or more embodiments, the light-emitting elements ED may be connected in series through the connection electrodes CTE to emit light.

Referring to FIG. 11, the first light-emitting element ED1 may emit light by a driving current applied through the first connection electrode CTE1 connected to one end and a second connection electrode CTE2 connected to the other end. The first connection electrode CTE1 may serve as the anode electrode supplying a driving current to the first light-emitting element ED1, and the second connection electrode CTE2 may serve as the cathode electrode. The second light-emitting element ED2 may emit light by a driving current applied through the second connection electrode CTE2 connected to one end and the third connection electrode CTE3 connected to the other end. The second connection electrode CTE2 may serve as the anode electrode supplying the driving current to the second light-emitting element ED2, and the third connection electrode CTE3 may serve as the cathode electrode. The third light-emitting element ED3 may emit light by a driving current applied through the third connection electrode CTE3 connected to one end and the fourth connection electrode CTE4 connected to the other end. The third connection electrode CTE3 may serve as the anode electrode supplying the driving current to the third light-emitting element ED3, and the fourth connection electrode CTE4 may serve as the cathode electrode. The fourth light-emitting element ED4 may emit light by a driving current applied through the fourth connection electrode CTE4 connected to one end and the fifth connection electrode CTE5 connected to the other end. The fourth connection electrode CTE4 may serve as the anode electrode supplying the driving current to the fourth light-emitting element ED4, and the fifth connection electrode CTE5 may serve as the cathode electrode.

According to one or more embodiments, the bank layer BNL may be around (e.g., may surround) the second emission area EMA2 and the sub-area SA of the first pixel PX1, and the first emission area EMA1 of the second pixel PX2.

The light-emitting elements ED may be sprayed (or applied) in the form of ink to the area partitioned by the bank layer BNL through an inkjet printing process. A solvent and light-emitting elements ED are included in the ink, and there is a very low probability that the light-emitting elements ED are not included in the ink. If there is no light-emitting elements ED in the ink, current flow between the connection electrodes CTE cannot be achieved through the light-emitting element ED, and driving defects (e.g., dark spots) may occur.

The bank layer BNL may divide the area to include a portion of the first sub-pixel SPX1 of the first pixel PX1 and a portion of the first sub-pixel SPX1 of the second pixel PX2 to form an area where ink is ejected.

As shown in FIG. 12, a case in the light-emitting element ED exist in the ink injected in the area where the first emission area EMA1 of the second pixel PX2 is partitioned and in which there is no light-emitting element ED in the ink sprayed in the area where the second emission area EMA2 of the second pixel PX2 is partitioned may occur. In this case, because the light-emitting element ED does not exist in the second emission area EMA2 of the second pixel PX2, the driving current applied to the first connection electrode CTE1 does not flow. Accordingly, the light-emitting elements ED located in the first emission area EMA1 of the second pixel PX2 are not connected in series and thus do not emit light.

On the other hand, because the light-emitting elements ED are located in the first emission area EMA1 and the second emission area EMA2 of the first pixel PX1, the first pixel PX1 may normally emit light. That is, in an area in which the first emission area EMA1 of the second pixel PX2 and the second emission area EMA2 of the first pixel PX1 are partitioned, the second emission area EMA2 of the first pixel PX1 may emit light. Accordingly, because light is emitted from one unit of light emission (e.g., light-emitting unit) partitioned by the bank layer BNL, occurrence of dark spots can be prevented or reduced.

In the display device 10 according to one or more embodiments, the sub-pixels SPXn located in the first direction DR1 may all emit the same color, and the bank layer may be formed to respectively include some of the sub-pixels located adjacent to the first direction DR1. Accordingly, even if a defect occurs because the light-emitting element ED is not located in any one sub-pixel SPXn, dark spots can be prevented or reduced from occurring by emitting light from the upper or lower sub-pixel of the corresponding sub-pixel SPXn.

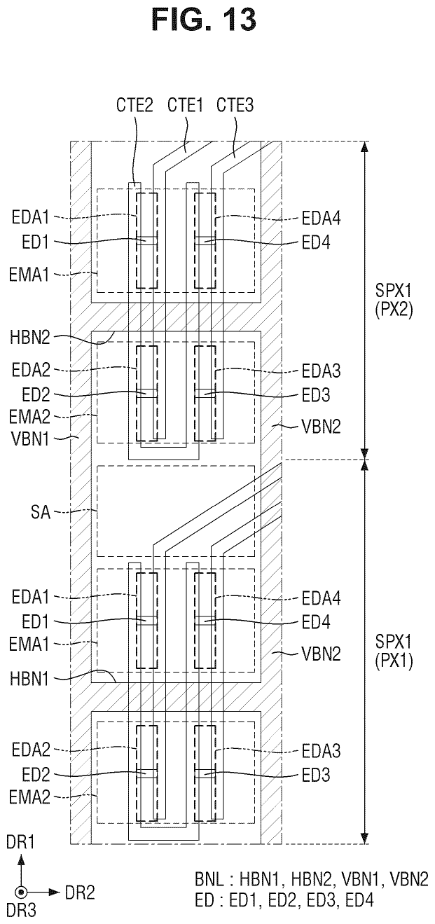

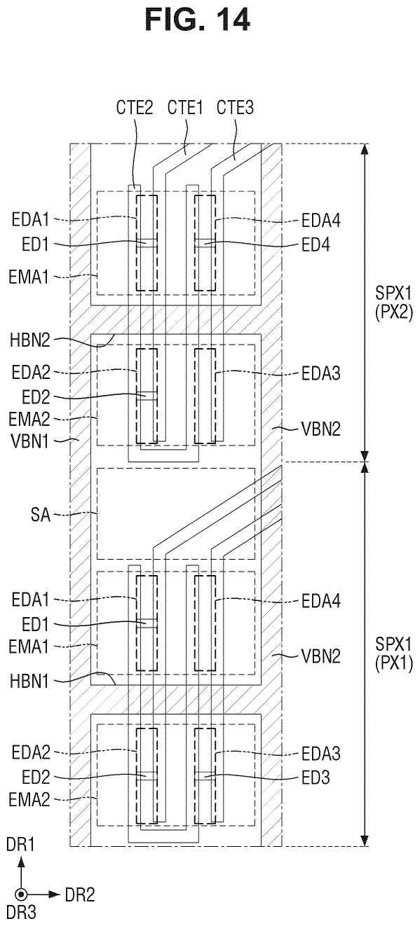

FIG. 13 is a plan view showing connection electrodes, a bank layer, and light-emitting elements of a display device according to one or more embodiments. FIG. 14 is a plan view showing a current flow of connection electrodes and light-emitting elements of display devices according to one or more embodiments.

Referring to FIGS. 13 and 14, the corresponding one or more embodiments are different from the above-described embodiments in that the number and shape of the connection electrodes CTE are different. Hereinafter, descriptions overlapping with the embodiments described above will be omitted and differences will be described.

The plurality of connection electrodes CTE may include a first connection electrode CTE1, a second connection electrode CTE2, and a third connection electrode CTE3. Although the arrangement of the connection electrodes CTEs is described using the first sub-pixel SPX1 of the first pixel PX1, it is to be noted that the connection electrodes CTE of the first sub-pixel SPX1 of the second pixel PX2 have the same arrangement.

The first connection electrode CTE1 may extend in the first direction DR1 and may cross and overlap the first connection HBN1 of the bank layer BNL. The first connection electrode CTE1 may be located over the first emission area EMA1 and the second emission area EMA2 of the first sub-pixel SPX1. The first connection electrode CTE1 may supply driving current to the first light-emitting element ED1 located in the first light-emitting element area EDA1 and the second light-emitting element ED2 located in the second light-emitting element area EDA2.

The second connection electrode CTE2 may extend in a direction opposite to the first direction DR1, may be bent in the second direction DR2, and again may extend in the first direction DR1. The second connection electrode CTE2 may be located in a shape surrounding the first connection electrode CTE1. For example, the second connection electrode CTE2 may be formed in a U-shape on a plane. The first portion and the second portion of the second connection electrode CTE2 may be parallel to and correspond to the first connection electrode CTE1, and the third portion thereof may connect the first portion and the second portion. The second connection electrode CTE2 may cross and overlap the first connection HBN1 of the bank layer BNL. The second connection electrode CTE2 may be located over the first emission area EMA1 and the second emission area EMA2 of the first sub-pixel SPX1. The second connection electrode CTE2 may serve as the cathode electrode of the first light-emitting element ED1 located in the first light-emitting element area EDA1 and the second light-emitting element ED2 located in the second light-emitting element area EDA2. In addition, the second connection electrode CTE2 may serve as the anode electrode of the third light-emitting element ED3 located in the third light-emitting element area EDA3 and the fourth light-emitting element ED4 located in the fourth light-emitting element area EDA4.

The third connection electrode CTE3 may extend in the first direction DR1 and may cross and overlap the first connection HBN1 of the bank layer BNL. The third connection electrode CTE3 may be located over the first emission area EMA1 and the second emission area EMA2 of the first sub-pixel SPX1. The third connection electrode CTE3 may serve as the cathode electrode of the fourth light-emitting element ED4 located in the fourth light-emitting element area EDA4 and the third light-emitting element ED3 located in the third light-emitting element area EDA3.

Among the light-emitting elements ED, the first light-emitting element ED1 and the fourth light-emitting element ED4 may be located in the first emission area EMA1, and the second light-emitting element ED2 and the third light-emitting element ED3 may be located in the second emission area EMA2. The first emission area EMA1 and the second emission area EMA2 may be located adjacent to each other with the bank layer BNL interposed therebetween. Accordingly, the first light-emitting element ED1 and the fourth light-emitting element ED4 may be located adjacent to the second light-emitting element ED2 and the third light-emitting element ED3 with the bank layer BNL interposed therebetween.

According to one or more embodiments, the bank layer BNL may be around (e.g., may surround) the first emission area EMA1 and the sub-area SA of the first sub-pixel SPX1 of the first pixel PX1 and the second emission area EMA2 of the first sub-pixel SPX1 of the second pixel PX2. The sub-area SA might not overlap the bank layer BNL and the light-emitting elements ED.

Referring to FIG. 14, the light-emitting elements ED may be sprayed (or applied) in the form of ink to an area partitioned by the bank layer BNL through an inkjet printing process. A solvent and light-emitting elements ED are included in the ink, and there is a very low probability that the light-emitting elements ED are not included in the ink. For example, the light-emitting elements ED may not be located in the fourth light-emitting element area EDA4 of the first sub-pixel SPX1 of the first pixel PX1 and the third light-emitting element area EDA3 of the first sub-pixel SPX1 of the second pixel PX2 within the area partitioned by the bank layer BNL.

In this case, because the second connection electrode CTE2 and the third connection electrode CTE3 of the first sub-pixel SPX1 of the first pixel PX1 are located across the third light-emitting element area EDA3 and the fourth light-emitting element area EDA4, the driving current may flow through the third light-emitting element ED3 located in the third light-emitting element area EDA3 even when the light-emitting element is not located in the fourth light-emitting element area EDA4 and the first sub-pixel SPX1 of the first pixel PX1 may normally emit light.

Similarly, because the second connection electrode CTE2 and the third connection electrode CTE3 of the first sub-pixel SPX1 of the second pixel PX2 are located across the third light-emitting element area EDA3 and the fourth light-emitting element area EDA4, the driving current may flow through the fourth light-emitting element ED4 located in the fourth light-emitting element area EDA4 even when the light-emitting element is not located in the third light-emitting element area EDA3 and the first sub-pixel SPX1 of the second pixel PX2 may normally emit light.

In the display device 10 according to one or more embodiments, the bank layer BNL may be formed to include a portion of each of the sub-pixels SPXn located adjacent to the first direction DR1. Therefore, even when the light-emitting element ED is not located in the light-emitting element area EDA of the sub-pixel SPXn, the driving current may flow to other light-emitting element area of the corresponding sub-pixel SPXn, thereby preventing or reducing dark spots from occurring.

In concluding the detailed description, those skilled in the art will appreciate that many variations and modifications can be made to the embodiments without substantially departing from the principles of the present disclosure. Therefore, the embodiments of the present disclosure are used in a generic and descriptive sense only and not for purposes of limitation.

What is claimed is:

1. A display device comprising:
a substrate comprising a first pixel and a second pixel that are adjacent to each other in a first direction, the first pixel comprising a sub-pixel and the second pixel comprising sub-pixel;
a first electrode and a second electrode above the substrate and extending in the first direction, the first electrode and the second electrode being in the sub-pixels;
a first insulating layer above the first electrode and the second electrode;
light-emitting elements above the first insulating layer between the first electrode and the second electrode;
a bank layer above the first insulating layer and dividing a first emission area and a second emission area of one of the sub-pixels and dividing a sub-area of the first pixel and a sub-area of the second pixel; and
a first connection electrode and a second connection electrode in the sub-pixels, the first connection electrode being connected to a first end of the light-emitting elements, and the second connection electrode connected to a second end of the light-emitting elements,
wherein the bank layer is around the first emission area and the sub-area of the sub-pixel of the first pixel and the second emission area of the sub-pixel of the second pixel.

2. The display device of claim 1, wherein the bank layer comprises:
a first extension and a second extension extending in the first direction and spaced in a second direction crossing the first direction; and
a first connection and a second connection connecting the first extension and the second extension, and spaced in the first direction.

3. The display device of claim 2, wherein the first extension is at one side of the sub-pixels of the first pixel and the second pixel, and
wherein the second extension is at an other side of the sub-pixels of the first pixel and the second pixel.

4. The display device of claim 2, wherein the first connection is in the sub-pixel of the first pixel between the first emission area and the second emission area of the sub-pixel of the first pixel.

5. The display device of claim 4, wherein the first connection electrode of the sub-pixel of the first pixel does not overlap the first connection, and
wherein the second connection electrode of the sub-pixel of the first pixel overlaps the first connection.

6. The display device of claim 2, wherein the second connection is in the sub-pixel of the second pixel between the first emission area and the second emission area of the sub-pixel of the second pixel.

7. The display device of claim 6, wherein the first connection electrode of the sub-pixel of the second pixel does not overlap the second connection, and
wherein the second connection electrode of the sub-pixel of the second pixel overlaps the second connection.

8. The display device of claim 2, wherein the first extension, the second extension, the first connection, and the second connection are around the second emission area and the sub-area of the sub-pixel of the first pixel and the first emission area of the sub-pixel of the second pixel.

9. The display device of claim 8, wherein the sub-area of the sub-pixel of the first pixel is between the second emission area of the sub-pixel of the first pixel and the first emission area of the sub-pixel of the second pixel.

10. The display device of claim 8, wherein the light-emitting elements are in the sub-pixels of the first pixel and the second pixel and comprise first light-emitting elements and second light-emitting elements.

11. The display device of claim 10, wherein the first light-emitting elements are in the second emission areas, and the second light-emitting elements are in the first emission areas, of the sub-pixels of the first pixel and the second pixel.

12. The display device of claim 10, wherein the first light-emitting elements and the second light-emitting elements do not overlap the first connection and the second connection of the bank layer.

13. The display device of claim 1, wherein the light-emitting elements overlap the first emission area and the second emission area and do not overlap the sub-area.

14. The display device of claim 1, further comprising:
a third connection electrode partially around the second connection electrode;
a fourth connection electrode facing the third connection electrode; and
a fifth connection electrode facing the fourth connection electrode,
wherein the light-emitting elements comprise a first light-emitting element between the first connection electrode and the second connection electrode, a second light-emitting element between the second connection electrode and the third connection electrode, a third light-emitting element between the third connection electrode and the fourth connection electrode, and a fourth light-emitting element between the fourth connection electrode and the fifth connection electrode.

15. A display device comprising:
a substrate comprising a first sub-pixel and a second sub-pixel spaced from each other in a first direction;
a bank layer above the substrate and dividing a first emission area and a second emission area of the first sub-pixel and a first emission area and a second emission area of the second sub-pixel;
a first connection electrode, a second connection electrode, and a third connection electrode in the first sub-pixel and the second sub-pixel, and extending across the first emission area and the second emission area; and
light-emitting elements above the substrate, and respectively between the first connection electrode and the second connection electrode and between the second connection electrode and the third connection electrode,
wherein the first connection electrode, the second connection electrode, and the third connection electrode cross and overlap the bank layer.

16. The display device of claim 15, wherein the bank layer is around the first emission area of the first sub-pixel and the second emission area of the second sub-pixel.

17. The display device of claim 15, wherein, in the first sub-pixel and the second sub-pixel, the light-emitting elements comprise a first light-emitting element and a second light-emitting element between the first connection electrode and the second connection electrode, and a third light-emitting element and a fourth light-emitting element between the second connection electrode and the third connection electrode.

18. The display device of claim 17, wherein the first light-emitting element and the fourth light-emitting element are in the first emission area and
wherein the second light-emitting element and the third light-emitting element are in the second emission area.

19. The display device of claim 18, wherein the first light-emitting element and the fourth light-emitting element are adjacent to the second light-emitting element and the third light-emitting element with the bank layer therebetween.

20. The display device of claim 15, further comprising a sub-area between the first emission area of the first sub-pixel and the second emission area of the second sub-pixel, and not overlapping the bank layer and the light-emitting elements.
